(19) United States
(12) Patent Application Publication
(10) Pub. No.: US 2023/0066878 A1
(43) Pub. Date: Mar. 2, 2023

(54) Light Emitting Display Device

(71) Applicant: LG Display Co., Ltd., Seoul (KR)

(72) Inventors: JuHun Min, Paju-si (KR); JinRyun Kim, Paju-si (KR); Jisu Yoon, Paju-si (KR); Sungrae Lee, Paju-si (KR)

(21) Appl. No.: 17/896,826

(22) Filed: Aug. 26, 2022

(30) Foreign Application Priority Data
Aug. 31, 2021 (KR) 10-2021-0115437

(51) Int. Cl. H01L 51/52; H01L 27/32

(52) U.S. Cl. CPC H01L 51/5275; H01L 27/322; H01L 51/5293

(57) ABSTRACT

A light emitting display device is disclosed. The light emitting device comprises a substrate including a plurality of pixels having a light emitting area, a light extraction portion including a curved portion in the light emitting area, a light emitting device layer over the light extraction portion and configured to emit light to a light emitting surface, and a light guide portion on the light emitting surface and including a light refraction pattern portion.

### CROSS-REFERENCE TO RELATED APPLICATION

This application claims the benefit of and priority to Republic of Korea Patent Application No. 10-2021-0115437 filed on Aug. 31, 2021, which is hereby incorporated by reference in its entirety.

### BACKGROUND

### Technical Field

The present disclosure relates to a light emitting display device.

### Discussion of the Related Art

A light emitting display device has a high response speed and has low power consumption. Unlike a liquid crystal display device, the light emitting display device is a self-emissive display device and does not require a separate light source. Thus, there is no problem in the viewing angle, whereby the light emitting display device is subject to a next generation flat panel display device.

The light emitting display device displays an image through light emission of an emitting device layer including an emission layer interposed between two electrodes.

However, since some of the light emitted from the emitting device layer is not emitted to the outside due to a total reflection at the interface between the emitting device layer and the electrode and/or a total reflection at the interface between the substrate and the air layer, the light extraction efficiency is reduced. Accordingly, the emitting display device has problems in that brightness is lowered due to low light extraction efficiency, and power consumption increases.

### SUMMARY

Accordingly, the present disclosure is directed to providing a light emitting display device that substantially obviates one or more problems due to limitations and disadvantages of the related art.

An aspect of the present disclosure is to provide a light emitting display device that can enhance light extraction efficiency of light which is emitted from a light emitting portion.

An aspect of the present disclosure is to provide a light emitting display device capable of reducing a degradation of black visibility characteristics caused by a reflection of external light.

The objects of the present disclosure are not limited to the aforesaid, but other objects not described herein will be clearly understood by those skilled in the art from descriptions below.

In one embodiment, a light emitting display device comprises: a substrate including a plurality of pixels having a light emitting area; a light extraction portion including a curved portion in the light emitting area; a light emitting device layer over the light extraction portion, the light emitting device configured to emit light to a light emitting surface in the light emitting area; and a light guide portion on the light emitting surface, the light guide portion including a light refraction pattern portion.

In one embodiment, light emitting display device comprises: a substrate including a plurality of pixels having a light emitting area; a planarization layer over the substrate, the planarization layer including a light extraction portion at a portion of the planarization layer in the light emitting area, the light extraction portion comprising a plurality of concave portions and a convex portion between the plurality of concave portions; a light emitting device layer over the light extraction portion, the light emitting device layer configured to emit light to a light emitting surface in the light emitting area; and a light guide portion on the light emitting surface, the light guide portion including a light refraction pattern portion, wherein the light refraction pattern portion includes a light refractive pattern that overlaps at least one or more among the plurality of concave portions and the convex portion.

In one embodiment, a display apparatus comprises: a substrate including a light emitting area; a subpixel on the substrate, the subpixel including a light emitting element configured to emit light in the light emitting area; a planarization layer between the substrate and the light emitting element, the planarization layer including a plurality of concave portions in the light emitting area and a plurality of convex portions in the light emitting area; and a light guide on the substrate, the light guide including a plurality of protrusions and a plurality of recesses in the light emitting area, wherein the plurality of protrusions and the plurality of recesses of the light guide portion overlap the plurality of concave portions and the plurality of convex portions of the planarization layer in the light emission area.

In the light emitting display device according to the present disclosure, the light extraction efficiency of light which is emitted from a light emitting portion may be improved.

In the light emitting display device according to the present disclosure, the degradation of black visibility characteristics by the reflection of external light may be reduced, thereby a real black in a non-driving or turning-off state may realize.

In addition to the effects of the present disclosure as mentioned above, additional advantages and features of the present disclosure will be clearly understood by those skilled in the art from the above description of the present disclosure.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain principles of the disclosure.

FIG. 1 schematically illustrates a light emitting display device according to an embodiment of the present disclosure;

FIG. 2 is a cross-sectional view illustrating one pixel shown in FIG. 1 according to an embodiment of the present disclosure;

FIG. 3 is an enlarged view of ‘A’ portion shown in FIG. 2 according to an embodiment of the present disclosure;

FIG. 4A conceptually illustrates a diffraction dispersion spectrum for reflected light of external light in a light emitting display device according to a comparative example;

FIG. 4B conceptually illustrates a diffraction dispersion spectrum for reflected light of external light in the light emitting display device according to an embodiment of the present disclosure;

FIG. 5 is a view for explaining a light guide portion according to an embodiment of the present disclosure;

FIGS. 6A to 6C illustrate various embodiments of the light guide portion shown in FIG. 5 according to an embodiment of the present disclosure;

FIG. 7 illustrates a light guide portion according to another embodiment of the present disclosure;

FIG. 8 illustrates a light guide portion according to another embodiment of the present disclosure;

FIG. 9 illustrates a light emitting display device according to another embodiment of the present disclosure;

FIG. 10 is a plan view illustrating a light extraction portion of a planarization layer shown in FIG. 9 according to an embodiment of the present disclosure;

FIG. 11 is a cross-sectional view along I-I′ of FIG. 9 according to an embodiment of the present disclosure;

FIGS. 12 to 17 illustrate light emitting display devices according to other embodiments of the present disclosure;

FIG. 18 is a cross-sectional view along II-II′ of FIG. 17 according to an embodiment of the present disclosure;

FIG. 19 illustrates a light emitting display device according to another embodiment of the present disclosure; and

FIGS. 20A to 20D are a photograph showing a black visibility characteristic of a light emitting display device according to an experimental example, and are photographs showing a black visibility of the light emitting display device according to some embodiments of the present disclosure.

### DETAILED DESCRIPTION

Advantages and features of the present disclosure, and implementation methods thereof will be clarified through following embodiments described with reference to the accompanying drawings. The present disclosure can, however, be embodied in different forms and should not be construed as limited to the embodiments set forth herein. Rather, these embodiments are provided so that this disclosure will be thorough and complete, and will fully convey the scope of the present disclosure to those skilled in the art. Furthermore, the present disclosure is only defined by the scopes of the appended claims.

A shape, a size, a ratio, an angle, and a number disclosed in the drawings for describing embodiments of the present disclosure are merely an example, and thus, the present disclosure is not limited to the illustrated details. Like reference numerals refer to like elements throughout. In the following description, when the detailed description of the relevant known technology is determined to unnecessarily obscure the important point of the present disclosure, the detailed description will be omitted. In a case where ‘comprise’, ‘have’, and ‘include’ described in the present disclosure are used, another part can be added unless ‘only-’ is used. The terms in a singular form may include plural forms unless noted to the contrary.

In construing an element, the element is construed as including an error range although there is no explicit description.

In describing a positional relationship, for example, when a position relation between two parts is described as ‘on-’, ‘over-’, ‘under-’, and ‘next-’, one or more other parts can be disposed between the two parts unless ‘just’ or ‘direct’ is used.

It will be understood that, although the terms “first,” “second,” and the like can be used herein to describe various elements, these elements should not be limited by these terms. These terms are only used to distinguish one element from another and may not define any order. For example, a first element could be termed a second element, and, similarly, a second element could be termed a first element, without departing from the scope of the present disclosure.

In describing elements of the present disclosure, the terms “first,” “second,” “A,” “B,” “(a),” “(b),” etc. may be used. These terms are intended to identify the corresponding elements from the other elements, and basis, order, or number of the corresponding elements should not be limited by these terms. The expression that an element is “connected,” “coupled,” or “adhered” to another element or layer the element or layer can not only be directly connected or adhered to another element or layer, but also be indirectly connected or adhered to another element or layer with one or more intervening elements or layers “disposed,” or “interposed” between the elements or layers, unless otherwise specified.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item.

Features of various embodiments of the present disclosure can be partially or overall coupled to or combined with each other and can be variously inter-operated with each other and driven technically as those skilled in the art can sufficiently understand. The embodiments of the present disclosure can be carried out independently from each other or can be carried out together in a co-dependent relationship.

Hereinafter, embodiments of the present disclosure will be described in detail with reference to the accompanying drawings. For convenience of description, a scale of each of elements illustrated in the accompanying drawings differs from a real scale, and thus, is not limited to a scale illustrated in the drawings.

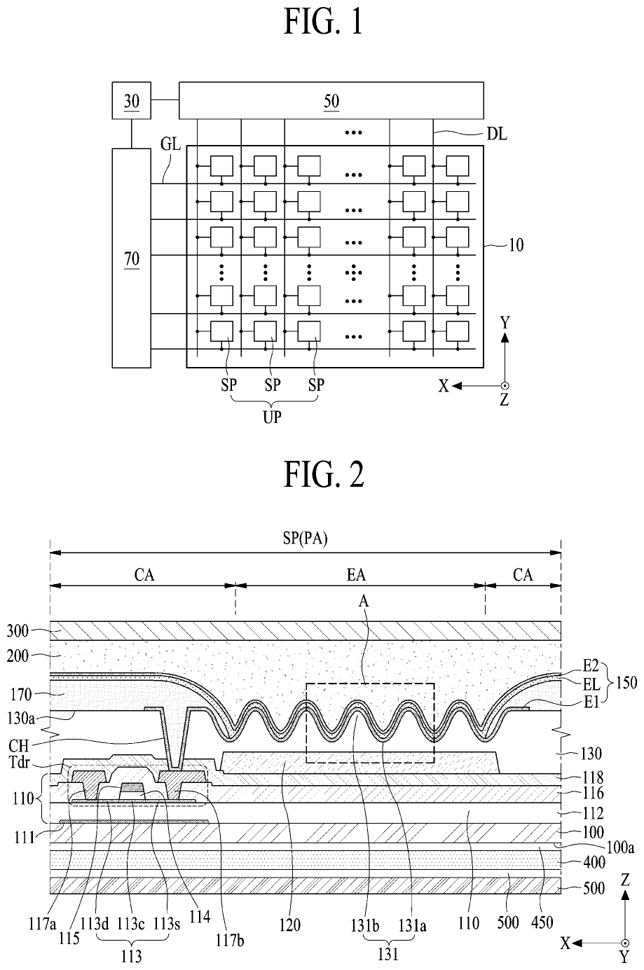

FIG. 1 schematically illustrates a light emitting display device according to an embodiment of the present disclosure.

Referring to FIG. 1, the light emitting display device according to an embodiment of the present disclosure may include a light emitting display panel 10, a control circuit 30, a data driving circuit 50, and a gate driving circuit 70.

The light emitting display panel 10 may include a display area and a non-display area. The display area is an area in which an image is displayed, and may be a pixel array area, an active area, a pixel array portion, a display portion, or a screen. For example, the display area may be disposed at a central area of the light emitting display panel 10. The non-display area is an area in which an image is not displayed, and may be a peripheral circuit area, a signal supply area, a non-active area, or a bezel area. The non-display area may be configured to surround the display area.

The light emitting display panel 10 includes a plurality of gate lines GL and a plurality of data lines DL provided at a substrate, and a plurality of pixels SP formed in a pixel area defined by the plurality of gate lines GL and the plurality of data lines DL.

Each of the plurality of pixels SP display images in accordance with gate signals supplied from the gate lines GL adjacent thereto and data signals supplied from the data lines DL adjacent thereto. Each of the plurality of pixels SP according to an embodiment of the present disclosure may include a pixel circuit provided in the pixel area and a light emitting device connected to the pixel circuit.

Each of the plurality of pixels SP may be a sub pixel and may be defined as a point light source emitting light. According to an embodiment of the present disclosure, at least three pixels SP arranged adjacent to each other among the plurality of pixels SP may configure a unit pixel (or one unit pixel) UP. For example, the unit pixel UP may include a red pixel, a green pixel, and a blue pixel in one embodiment. In other embodiments, the unit pixel UP may further include a white pixel in addition to a red pixel, a green pixel, and a blue pixel. Additionally, the unit pixel UP may further include a light transmitting portion disposed around the pixel.

The control circuit 30 may generate pixel data for each pixel corresponding to each of the plurality of pixels SP based on externally input image data. The control circuit 30 may generate a data control signal based on a timing synchronization signal and provide the generated data control signal to the data driving circuit 50. The control circuit 30 may generate a gate control signal based on the timing synchronization signal and provide the generated gate control signal to the gate driving circuit 70.

The data driving circuit 50 may be connected with the plurality of data lines DL provided at the light emitting display panel 10. The data driving circuit 50 may receive the pixel data for each pixel and the data control signal provided from the control circuit 30 and receive a plurality of reference gamma voltages provided from a power circuit. The data driving circuit 50 may converts the pixel data for each pixel to a pixel data for each pixel signal (or voltage) by using the data control signal and the plurality of reference gamma voltages and supply the converted pixel data for each pixel signal to the corresponding data line DL.

The gate driving circuit 70 may be connected with the plurality of gate lines GL provided at the light emitting display panel 10. The gate driving circuit 70 may generate gate signals in accordance with a preset order based on the gate control signal supplied from the control circuit 30 and supply the gate signals to the corresponding gate lines GL.

The gate driving circuit 70 according to an embodiment of the present disclosure may be integrated with one edge or both edges of the display panel 10 in accordance with a manufacturing process of the thin film transistor, and may be connected with the plurality of gate lines GL by a one-to-one correspondence. For example, the gate driving circuit may include a generally known shift register.

The gate driving circuit 70 according to another embodiment of the present disclosure may be configured as an integrated circuit, may be mounted at the substrate or a flexible circuit film, and may be connected with the plurality of gate lines GL by a one-to-one correspondence.

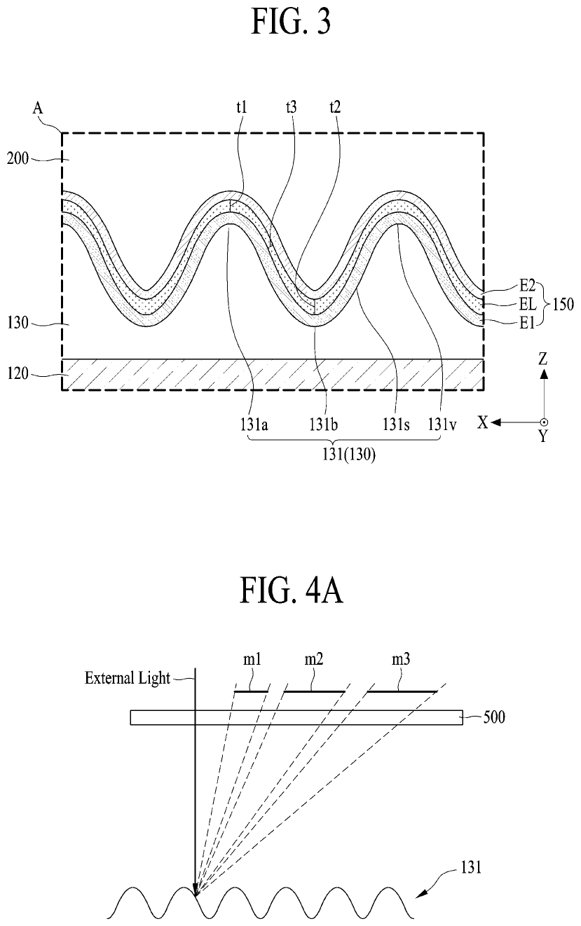

FIG. 2 is a cross-sectional view illustrating one pixel shown in FIG. 1 according to one embodiment, and FIG. 3 is an enlarged view of ‘A’ portion shown in FIG. 2 according to one embodiment.

Referring to FIGS. 2 and 3, the light emitting display device (or light emitting display panel) according to an embodiment of the present disclosure may include a plurality of pixels (or sub pixels) SP.

Each of the plurality of pixels SP may be disposed at a pixel area PA. The pixel area PA according to an embodiment of the present disclosure may include a circuit area CA and a light emitting area EA. The circuit area CA may be spatially separated from the light emitting area EA in the pixel area PA, but is not limited thereto. For example, at least a portion of the circuit area CA may overlap the light emitting area EA in the pixel area PA. For example, the circuit area CA may overlap an entire area of the light emitting area EA in the pixel area PA, or may be disposed under the light emitting area EA. The light emitting area EA may be an opening region or a light emitting region. For example, the circuit area CA may be a non-light emitting region or a non-opening region. The pixel area PA according to another embodiment of the present disclosure may further include a light transmitting portion disposed around at least one of the light emitting area EA and the circuit area CA. For example, the unit pixel may include a light emitting area for each pixel corresponding to each of the plurality of pixels SP, and a light transmitting portion disposed around each of the plurality of pixels SP. In this case, the light emitting display device may implement a transparent light emitting display device due to light transmission of the light transmitting portion.

The light emitting display device (or the light emitting display panel) according to an embodiment of the present disclosure may include a substrate 100 (e.g., a first substrate), an encapsulation portion 200, an opposite substrate 300 (e.g., a second substrate opposite the first substrate), and a light guide portion 400.

The substrate 100 includes a thin film transistor, and may be a first substrate, a base substrate, a lower substrate, a transparent glass substrate, a transparent plastic substrate, or a base member.

The light emitting display device or the substrate 100 may include a pixel circuit layer 110, a planarization layer 130 and a light emitting device layer 150.

The pixel circuit layer 110 may include a buffer layer 112, a pixel circuit, and a protection layer 118.

The buffer layer 112 may be disposed at an entire area of the first surface (or front surface) of the substrate 100. The buffer layer 112 may prevent or at least reduce materials contained in the substrate 100 from spreading to a transistor layer during a high-temperature process in the manufacturing of the thin film transistor, or may prevent external water or moisture from permeating into the light emitting device layer 150. Selectively, according to some embodiments of the present disclosure, the buffer layer 112 may be omitted.

The pixel circuit may include a driving thin film transistor Tdr disposed at the circuit area CA of each pixel P (or sub pixel SP). The driving thin film transistor Tdr may include an active layer 113, a gate insulating film 114, a gate electrode 115, an insulating interlayer 116, a drain electrode 117a, and a source electrode 117b.

The active layer 113 included in the driving thin film transistor Tdr may be configured with a semiconductor material based on any one of amorphous silicon, polycrystalline silicon, oxide, and organic materials.

The gate insulating film 114 may be provided over a channel region 113c of the active layer 113. As an example, the gate insulating film 114 may be provided at an island shape only over the channel region 113c of the active layer 113, or may be provided over the entire front surface of the buffer layer 112 or substrate 100 including the active layer 113.

The gate electrode 115 may be disposed over a gate insulating layer 114 to overlap a channel region 113c of an active layer 113.

The insulating interlayer 116 may be provided over the gate electrode 115, and a drain region 113d and a source region 113s of the active layer 113. The insulating interlayer 116 may be formed at the entire front surface of the buffer layer 112 or substrate 100. For example, the insulating interlayer 116 may be configured with an inorganic material or an organic material.

A drain electrode 117a may be disposed over an insulating interlayer 116 to be electrically connected to a drain region 113d of the active layer 113. A source electrode 117b may be disposed on the insulating interlayer 116 to be electrically connected to a source region 113s of the active layer 113.

The pixel circuit may further include at least one capacitor and at least one switching thin film transistor disposed at the circuit area CA together with the driving thin film transistor Tdr.

The light emitting display device according to an embodiment of the present disclosure may further include a light shielding layer 111 provided below at least one active layer 113 among the driving thin film transistor Tdr, a first switching thin film transistor, and a second switching thin film transistor such that the light shielding layer 111 is closer to the substrate 100 than the active layer 113. The light shielding layer 111 may be configured to reduce or prevent a change in a threshold voltage of the thin film transistor caused by external light.

The protection layer 118 may be provided over the substrate 100 to cover (or overlay) the pixel circuit. For example, the protection layer 118 may be configured to cover (or overlay) the drain electrode 117a and the source electrode 117b of the driving thin film transistor Tdr and the insulating interlayer 116. For example, the protection layer 118 may be formed of an inorganic insulating material and may be referred to as a passivation layer.

The planarization layer 130 may be provided over the substrate 100 to cover (or overlay) the protection layer 118. The planarization layer 130 may be provided at the entire display area and the remaining portions of the non-display area except the pad area. For example, the planarization layer 130 may include an extension portion (or expansion portion) extended or expanded from the display area to the remaining portions of the non-display area except the pad area. Accordingly, the planarization layer 130 may have a relatively large size than the display area.

The planarization layer 130 according to an embodiment of the present disclosure has a relatively large thickness so that the planarization layer 130 may provide a planarized surface over the pixel circuit layer 110. For example, the planarization layer 130 may be formed of an organic material such as photo acrylic, benzocyclobutene, polyimide, and fluorine resin, but are not limited thereto.

The planarization layer 130 may include a light extraction portion 131 disposed at each pixel P.

According to an embodiment of the present disclosure, the light extraction portion 131 may be formed in the planarization layer 130 to overlap the light emitting area EA defined at the pixel area PA of each pixel P. According to another embodiment of the present disclosure, the light extraction portion 131 may be provided in the entire surface of the planarization layer 130.

The light extraction portion 131 may be formed in the planarization layer 130 to have a curved portion (e.g., a curved surface or a non-flat portion). The light extraction portion 131 may be formed in the planarization layer 130 to have a bumpy (or uneven or mountain and valley) shape. The light extraction portion 131 may have a larger size than the light emitting area EA. For example, the light extraction portion 131 may be referred to as a curved pattern portion, a bending pattern portion, a bumpy pattern portion, an uneven pattern portion, a micro lens, or a light scattering pattern.

The light extraction portion 131 according to an embodiment of the present disclosure includes a plurality of concave portions 131a, and a plurality of convex portions 131b such that each of the plurality of concave portions 131a is disposed between at least two of the convex portions 131b.

Each of the plurality of concave portions 131a may be disposed between at least two of the convex portions 131b. Each of the plurality of concave portions (or depressions) 131a may be concavely implemented from an upper surface (or the flat surface) 130a of the planarization layer 130 such that each concave portion 131a extends towards the substrate 100. Each of the plurality of concave portions 131a may be configured to have the same depth with respect to an upper surface 130a of the planarization layer 130, but is not limited thereto, some of the plurality of concave portions 131a may have different depths within an error or tolerance range for a patterning process of the light extraction portion 131. For example, a lower surface (or a bottom surface) of the plurality of concave portions 131a may be positioned between the upper surface 130a of the planarization layer 130 and the substrate 100.

The convex portions (or protruding portions) 13 lb may be formed to be connected to each other between the plurality of concave portions 131a. The protruding portion 131b may be formed to surround each of the plurality of concave portions 131a. Accordingly, the planarization layer 130 overlapping the light emitting area EA may include the plurality of concave portions 131a surrounded by the convex portions 131b. For example, the convex portion 131b surrounding one concave portion 131a may two-dimensionally have a rectangular shape, a honeycomb shape, or a circle shape according to the arrangement structure of each of the plurality of concave portions 131a in a plan view.

The convex portion 131b may be provided at the planarization layer 130 overlapped the light emitting area EA to have a shape that may maximize external extraction efficiency of light emitted from a pixel P based on an effective light emission area of the light emitting device layer 150. The convex portion 131b changes the traveling path of the light emitted from the light emitting device layer 150 toward the light emitting surface, and emits light totally reflected in the light emitting device layer 150 toward the light emitting surface, thereby preventing or reducing degradation of light extraction efficiency due to light trapped in the light emitting device layer 150.

The convex portion 131b according to an embodiment of the present disclosure may include a bottom portion (or bottom surface), an upper portion (or upper surface) 131v over the bottom portion, and an inclined portion 131s between the bottom portion and the upper portion 131v.

The upper portion 131v of the convex portion 131b may have a convex curved shape (e.g., curved surface). For example, the upper portion 131v of the convex portion 131b may include a dome or bell structure having a convex cross-sectional shape, but is not limited thereto.

The inclined portion 131s of the convex portion 131b may have a curved shape (e.g., curved surface) between the bottom portion and the upper portion 131v. The inclined portion 131s of the convex portion 131b may form or implement the concave portion 131a. For example, the inclined portion 131s of the convex portion 131b may be an inclined surface or a curved portion. The inclined portion 131s of the convex portion 131b according to an embodiment of the present disclosure may have a cross-sectional structure having Gaussian curve. In this case, the inclined portion 131s of the convex portion 131b may have a tangent slope which increases progressively from the bottom portion to the upper portion 131v, and then decreases progressively.

The light emitting device layer 150 may be disposed over the light extraction portion 131 overlapping the light emitting area EA of each pixel P. The light emitting device layer 150 may include a first electrode E1, a light emitting layer EL, and a second electrode E2. For example, the first electrode E1, the light emitting layer EL, and the second electrode E2 may be configured to emit the light toward the substrate 100 according to a bottom emission type, but is not limited thereto. Thus, also a top emission type is possible.

The first electrode E1 may be formed over the planarization layer 130 of the pixel area PA and may be electrically connected to the source electrode 117b of the driving thin film transistor Tdr. One end of the first electrode E1 which is close to the circuit area CA may be electrically connected to the source electrode 117b of the driving thin film transistor Tdr via an electrode contact hole CH provided at or passing through the planarization layer 130 and the protection layer 118.

As the first electrode E1 directly contacts the light extraction portion 131, the first electrode E1 has a shape corresponding to (e.g., matches) the shape of the light extraction portion 131. As the first electrode E1 is formed (or deposited) over the planarization layer 130 to have a relatively small thickness, the first electrode E1 may have a surface morphology (or second surface shape) corresponding to a surface morphology (or first surface shape) of the light extraction portion 131 including the convex portion 131b and the plurality of concave portions 131a. For example, the first electrode E1 is formed in a conformal shape based on the surface shape (morphology) of the light extraction portion 131 by a deposition process of a transparent conductive material, whereby the first electrode E1 may have a cross-sectional structure whose shape is the same as the light extraction portion 131.

The light emitting layer EL may be formed over the first electrode Eland may directly contact the first electrode E1. As the light emitting layer EL is formed (or deposited) over the first electrode E1 to have a relatively large thickness in comparison to the first electrode E1, the light emitting layer EL may have a surface morphology (or third surface shape) which is different from the surface morphology in each of the plurality of concave portions 131a and the convex portion 131b or the surface morphology of the first electrode E1. For example, the light emitting layer EL may be formed in a non-conformal shape which does not conform to the surface shape (or morphology) of the first electrode E1 by a deposition process, whereby the light emitting layer EL may have a cross-sectional structure whose shape may be different from the first electrode E1.

The light emitting layer EL according to an embodiment of the present disclosure has a thickness gradually thicker toward the bottom surface of the convex portion 131b or the concave portion 131a. For example, the light emitting layer EL may be formed of a first thickness t1 over the upper portion 131v of the convex portion 131b, may be formed of a second thickness t2 that is thicker than the first thickness t1 over the bottom surface of the concave portion 131a, and may be formed over an inclined portion (or a curved portion) 131s of the convex portion 131b to have a third thickness t3 that is less than the first thickness t1. Herein, each of the first, second, and third thicknesses t1, t2, and t3 may be the shortest distance between the first electrode E1 and the second electrode E2 over the upper portion 131v of the convex portion 131b, the bottom surface of the concave portion 131a and over the inclined portion (or the curved portion) 131s of the convex portion 131b, respectively.

The light emitting layer EL according to an embodiment of the present disclosure includes two or more organic light emitting layers for emitting white light. As an example, the light emitting layer EL may include a first organic light emitting layer and a second organic light emitting layer to emit white light by mixing a first light and a second light. For example, the first organic light emitting layer may include any one selected of a blue organic light emitting layer, a green organic light emitting layer, a red organic light emitting layer, a yellow organic light emitting layer, and a yellow-green organic light emitting layer to emit the first light. For example, the second organic light emitting layer may include an organic light emitting layer capable of emitting the second light to obtain white light in the light emitting layer EL by mixing the first light of a blue organic light emitting layer, a green organic light emitting layer, a red organic light emitting layer, a yellow organic light emitting layer, or a yellow-green organic light emitting layer. The light emitting layer EL according to another embodiment of the present disclosure may include any one selected of a blue organic light emitting layer, a green organic light emitting layer, and a red organic light emitting layer.

The second electrode E2 may be formed at the light emitting layer EL and may directly contact the light emitting layer EL. The second electrode E2 may be formed (or deposited) at the light emitting layer EL to have a relatively smaller thickness compared to the light emitting layer EL. The second electrode E2 may be formed (or deposited) at the light emitting layer EL to have a relatively small thickness, and thus may have a surface morphology corresponding to the surface morphology of the light emitting layer EL. For example, the second electrode E2 may be formed in a conformal shape corresponding to the surface shape (or morphology) of the light emitting layer EL by a deposition process, whereby the second electrode E2 may have the same cross-sectional structure as the light emitting layer EL.

The second electrode E2 according to an embodiment of the present disclosure may include a metal material having a high reflectance to reflect the incident light emitted from the light emitting layer EL toward the substrate 100. For example, the second electrode E2 may include a single-layered structure or multi-layered structure of any one material selected from aluminum (Al), argentums (Ag), molybdenum (Mo), aurum (Au), magnesium (Mg), calcium (Ca), or barium (B a), or alloy of two or more materials selected from aluminum (Al), argentums (Ag), molybdenum (Mo), aurum (Au), magnesium (Mg), calcium (Ca), or barium (B a). The second electrode E2 may include an opaque conductive material having high reflectance. This particularly necessary for a bottom emission type. In a top emission type, the E1 is made of metal and E2 is transparent.

The external extraction efficiency of the light generated by the light emitting layer EL may be increased by the light extraction portion 131. The light extraction portion 131 changes the traveling path of light emitted from the light emitting device layer 150, to thereby increase the light extraction efficiency. The concave portion 131a or the convex portion 131b of the light extraction portion 131 may have a shape that can maximize (e.g., increase) the external extraction efficiency of light generated by the light emitting layer EL. For example, the convex portion 131b of the light extraction portion 131 changes the traveling path of the light emitted from the light emitting device layer 150 to the light emitting surface (or light extraction surface), to thereby increase the external extraction efficiency of the light emitted from the light emitting device layer 150. For example, the convex portion 131b prevents or reduces degradation of the light extraction efficiency caused by the light which is trapped in the light emitting device layer 150 by repeating total reflection between the first electrode E1 and the second electrode E2 of the light emitting device layer 150 without traveling to the light emitting surface.

The light emitting display device according to an embodiment of the present disclosure may further include a bank layer 170 configured to define the light emitting area EA of each pixel P.

The bank layer 170 may be disposed at an edge portion of the first electrode E1 and at the planarization layer 130. The bank layer 170 may be formed of an organic material such as benzocyclobutene (BCB)-based resin, acrylic-based resin, polyimide resin, or the like. For example, the bank layer 170 may be formed of a photosensitizer including a black pigment. In this case, the bank layer 170 may also function as a light shielding member between the adjacent pixels.

The bank layer 170 may be disposed over the upper surface 130a of the planarization layer 130 to cover (or overlay) the edge portion of the first electrode E1 extending onto the circuit area CA of the pixel area PA and may be disposed to cover (or overlay) the edge portion of the light extraction portion 131. The light emitting area EA defined by the bank layer 170 may be smaller in size than the light extraction portion 131 of the planarization layer 130 in a two-dimensional structure.

The light emitting layer EL of the light emitting device layer 150 may be provided over the first electrode E1, the bank layer 170, and a step difference portion between the first electrode E1 and the bank layer 170. In this case, when the light emitting layer EL is provided with a small thickness at the step difference portion between the first electrode E1 and the bank layer 170, an electrical contact (or short) may occur between the second electrode E2 and the first electrode E1 due to a thickness reduction of the light emitting layer EL. To prevent this problem, one end (or an outermost bank line) of the bank layer 170 may be disposed to be covered (or overlaid) the edge portion of the light extraction portion 131 to reduce a step difference between the first electrode E1 and the bank layer 170. Therefore, the electric contact (or short) between the first electrode (for example, anode electrode) E1 and the second electrode (for example, cathode electrode) E2 may be prevented or at least reduced due to the end of the bank layer 170 disposed at the step portion between the first electrode E1 and the bank layer 170.

The light emitting display device according to an embodiment of the present disclosure may further include a color filter layer 120.

The color filter layer 120 may be disposed between the substrate 100 and the planarization layer 130 to overlap at least one light emitting area EA. The color filter layer 120 according to an embodiment of the present disclosure may be disposed between the protection layer 118 and the planarization layer 130 to overlap the light emitting area EA. The color filter layer 120 according to another embodiment of the present disclosure may be disposed between the substrate 100 and the insulating interlayer 116 or between insulating interlayer 116 and the protection layer 118 to overlap the light emitting area EA.

The color filter layer 120 may have a larger size than the light emitting area EA. For example, the color filter layer 120 may be larger than the light emitting area EA, and/or may be smaller than the light extraction portion 131 of the planarization layer 130, but is not limited thereto, and the color filter layer 120 may be larger than the light extraction portion 131 of the planarization layer 130. For example, an edge portion of the color filter layer 120 may have a size corresponding to the entire pixel area PA of each pixel P.

The color filter layer 120 according to an embodiment of the present disclosure may include a color filter which transmits only the wavelength of a color set in the pixel P (or subpixel) among the light emitted (or extracted) from the light emitting device layer 150 toward the substrate 100. For example, the color filter layer 120 may transmit only the red wavelength, green wavelength, or blue wavelength. When the unit pixel UP comprises adjacent first to fourth pixels P, the color filter layer provided at the first pixel may include a red color filter, the color filter layer provided at the second pixel may include a green color filter, and the color filter layer provided at the third pixel may include a blue color filter. The fourth pixel may not include a color filter layer or may include a transparent material to compensate a step difference between adjacent pixels, thereby emitting white light.

The color filter layer 120 according to another embodiment of the present disclosure may include a quantum dot to emit light of a color set in the corresponding pixel P (or subpixel) based on the blue light emitted from the light emitting device layer 150 toward the substrate 100. Optionally, the color filter layer 120 according to another embodiment of the present disclosure may be implemented with a sheet (or a film) including a quantum dot layer disposed overlapped the light emitting area EA of the plurality of pixels P (or subpixel) and may be attached to the light extraction surface.

The encapsulation portion 200 may be formed over substrate 100 to cover (or overlay) the light emitting device layer 150. For example, the encapsulation portion 200 may surround the display area. For example, the encapsulation portion 200 may be disposed between the substrate 100 and the opposite substrate 300 and may surround the display area. The encapsulation portion 200 may protect the thin film transistor and the light emitting layer EL or the like from external impact and prevent oxygen or/and water and particles from being permeated into the light emitting layer EL.

The encapsulation portion 200 according to an embodiment of the present disclosure may include a plurality of inorganic encapsulation layer. The encapsulation portion 200 may further include at least one organic encapsulation layer interposed between the plurality of inorganic encapsulation layer. The organic encapsulation may be expressed as a particle overlay layer.

The encapsulation portion 200 according to another embodiment of the present disclosure may further include a filler completely surrounding the entire display area. In this case, the opposite substrate 300 may be bonded to the substrate 100 by using the filler (or a filling member). The filler may include a getter material that absorbs oxygen or/and water.

The opposite substrate 300 may be coupled to the encapsulation portion 200. The opposite substrate 300 may be made of a plastic material, a glass material, or a metal material. For example, when the encapsulation portion 200 includes a plurality of inorganic encapsulation layers, the opposite substrate 300 may be omitted.

Alternatively, when the encapsulation portion 200 is changed to a filler, the opposite substrate 300 may be combined with the filler, in this case, the opposite substrate 300 may be made of a plastic material, a glass material, or a metal material.

The light guide portion 400 may be configured or disposed at the light emitting display device or light emitting surface 100a of the display panel. The light guide portion 400 may be configured or disposed at a second surface (or light emitting surface) 100a opposite to a first surface of the substrate 100. The light guide portion 400 may overlap the light extraction portion 131 in each pixel. For example, the substrate 100 may be disposed between the light guide portion 400 and the light extraction portion 131. The light guide portion 400 may be disposed under the substrate 100 or in the light emission direction, so that in case of a bottom emission type the light is emitted through the substrate 100 and the then through the light guide portion 400.

The light guide portion 400 according to an embodiment of the present disclosure may be combined with (or coupled to) the second surface 100a of the substrate 100 by using an adhesive member (or first transparent adhesive member) 450. For example, the light guide portion 400 may be combined with (or coupled to) the entire second surface 100a of the substrate 100 by using the adhesive member 450. For example, the light guide portion 400 may have the same size as the second surface 100a of the substrate 100.

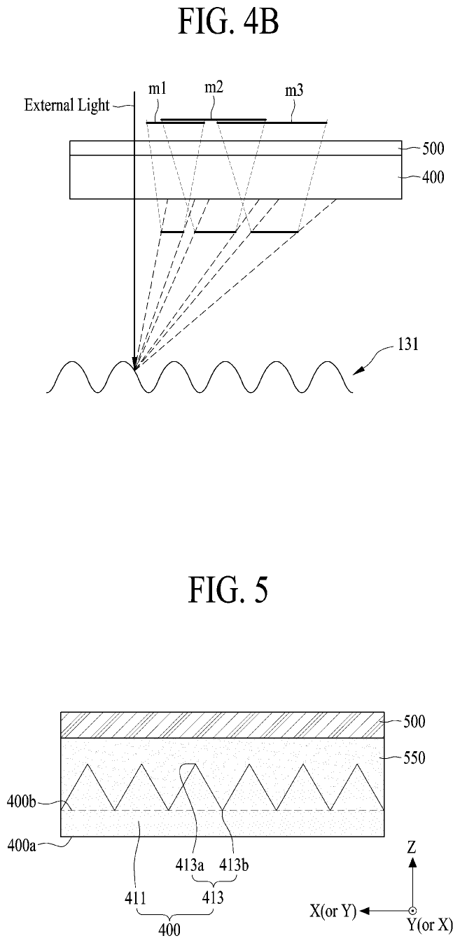

The light guide portion 400 may be configured to reduce degradation of a black visibility characteristic of the display panel due to the reflection of external light in a non-driving or turning-off state of the light emitting display device. For example, when the external light is incident on the light extraction portion 131, double-reflected light is generated by the curved portion (or curved pattern) of the light extraction portion 131, which may be emitted to the outside through the light emitting surface according to the birefringence effect of the thin film. The reflected light can generate a rainbow pattern (or rainbow stain pattern) which has a rainbow color and spreads in a radial form due to the light distribution characteristics according to the difference between material characteristics of the light emitting device layer 150 and the difference in refractive angle for each wavelength caused by the difference in refractive index for each layer. For example, the reflected light may generate a rainbow pattern in a radial form according to destructive interference and/or constructive interference of the light, to thereby degrade the black visibility characteristics. For example, as shown in FIG. 4A, the diffraction dispersion spectrum according to the diffraction orders m1, m2, and m3 of the reflected light by the curved portion (or curved pattern) of the light extraction portion 131, which serves as the diffraction grating pattern, is regularly arranged according to the reflection diffraction grating rule (or equation), whereby the rainbow pattern of the radial may be generated. The rainbow pattern of the radial form spreads in a radial shape with respect to the curved portion of the light extraction portion 131, and the size and intensity of the light (or diffraction dispersion spectrum) distributed according to the reflection diffraction grating rule may vary with respect to the curved portion of the light extraction portion.

The light guide portion 400 according to an embodiment of the present disclosure may be configured to further re-disperse the diffraction dispersion spectrum of the reflected light generated from the curved portion of the light extraction portion 131 on the basis of light refraction principle according to a cross-sectional shape having the refractive index difference. For example, as shown in FIG. 4B, the light guide portion 400 may reduce the intensity of the diffraction dispersion spectrum of the reflected light generated according to the pattern of the light extraction portion 131 or re-disperse the diffraction dispersion spectrum so as to greatly expand the size of the spectrum, and thus, the generation of rainbow pattern in a radial form may be reduced or minimized by mixing between adjacent spectra according to the diffraction orders m1, m2, and m3 of the reflected light. For example, the light guide portion 400 may be a light guide pattern portion, a light refraction portion, a light refraction member, a spectrum dispersion portion, a spectrum reduction portion, or a diffraction spectrum dispersion portion.

The light emitting display device or the light emitting display panel 10 according to an embodiment of the present disclosure may further include a polarization member 500 disposed over the light guide portion 400.

The polarization member 500 may be configured to block external light reflected by the light extraction portion 131 and the pixel circuit, or the like. For example, the polarization member 500 may be configured as a circularly polarization member or a circularly polarization film.

The polarization member 500 may be disposed at or coupled to a rear surface of the light guide portion 400 by using a coupling member (or a second transparent adhesive member) 550. Therefore, the polarization member 500 may be disposed between the light emitting surface 100a and the polarization member 500.

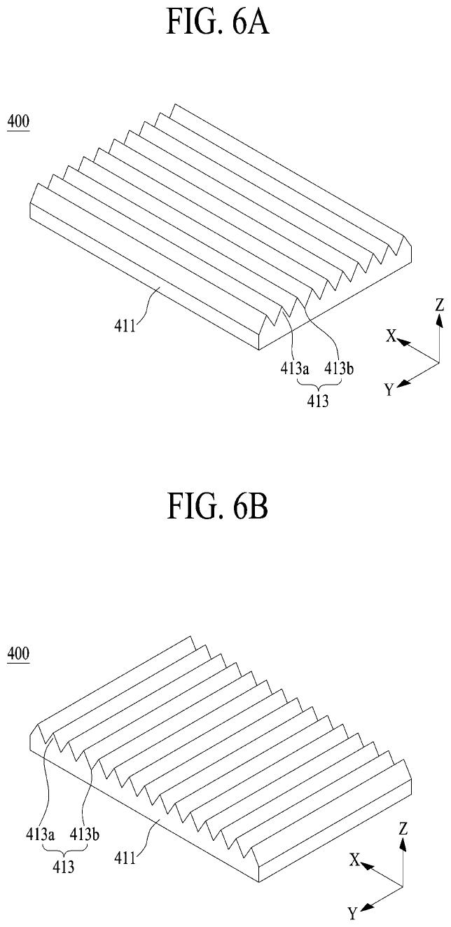

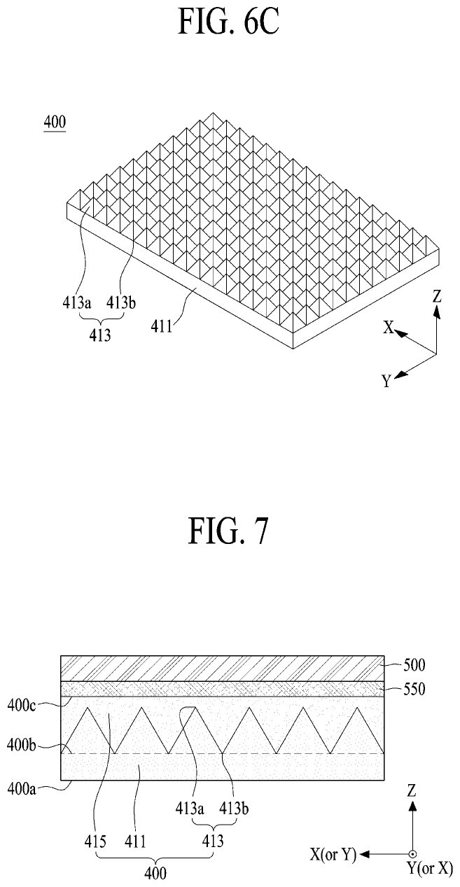

FIG. 5 is a view for explaining the light guide portion according to an embodiment of the present disclosure. FIG. 5 is a cross-sectional view illustrating the light guide portion and the polarization member shown in FIG. 2 according to an embodiment of the present disclosure. FIGS. 6A to 6C illustrate various embodiments of the light guide portion shown in FIG. 5.

Referring to FIGS. 2 and 5, the light guide portion 400 according to an embodiment of the present disclosure may be configured as a material having a predetermined refractive index. For example, the light guide portion 400 may be made of a plastic material having a first refractive index, but is not limited thereto.

The light guide portion 400 according to an embodiment of the present disclosure may include a base member 411 and a light refraction pattern portion 413.

The base member 411 may be configured as a material having a predetermined refractive index. For example, the base member 411 may be configured as a plastic film having a first refractive index. The base member 411 may be disposed at or coupled to the second surface 100a of the substrate 100 by using an adhesive member (or a first transparent adhesive member). For example, the light guide portion 400 or a first surface 400a of the base member 411 may be disposed at or coupled to the second surface 100a of the substrate 100 by using an adhesive member (or a first transparent adhesive member). For example, the base member 411 may cover the entire second surface 100a of the substrate 100.

The light refraction pattern portion 413 may be configured to refract incident light according to a refractive index difference with the base member 411. The light refraction pattern portion 413 may be configured to change a traveling path for each wavelength of light incident according to the refractive index difference. The light refraction pattern portion 413 may be configured to further distribute the diffraction dispersion spectrum of the incident light according to the refractive index difference. For example, the light refraction pattern portion 413 may be a first refractive medium or a high refractive medium, but is not limited thereto.

The light refraction pattern portion 413 may be formed at a second surface 400b of the base member 411. The light refraction pattern portion 413 may include a refractive pattern protruding from the second surface 400b of the base member 411 along a thickness direction Z of the base member 411.

The light refraction pattern portion 413 according to an embodiment of the present disclosure may include a plurality of protrusion patterns 413a (e.g., a plurality of protrusions) and a plurality of recessed patterns 413b (e.g., a plurality of recesses).

Each of the plurality of protrusion patterns 413a may protrude from the second surface 400b of the base member 411 along the thickness direction Z of the base member 411 away from the second surface 400b. Each of the plurality of protrusion patterns 413a may include a line shape having a predetermined length and a predetermined width. According to an embodiment of the present disclosure, the plurality of protrusion patterns 413a may have a triangular cross-sectional structure such as a regular triangle or an isosceles triangle, or the like. For example, each of the plurality of protrusion patterns 413a may be a prism. For example, the protrusion pattern 413a may be a first refractive medium, a high refractive medium, a light refraction pattern, a mountain pattern, or a mountain portion, but is not limited thereto.

The length direction of each of the plurality of protrusion patterns 413a according to an embodiment of the present disclosure may be parallel to a first direction X. For example, as shown in FIG. 6A, each of the plurality of protrusion patterns 413a extends along in the first direction X and may be arranged in parallel along a second direction Y which intersects with the first direction X. For example, the cross angle between the first direction X and the second direction Y may be 90 degrees in the same plane. For example, the first direction X may be either a horizontal length direction or a long side length direction of any one of the light emitting display panel, the substrate 100, and the base member 411. For example, the second direction Y may be a vertical length direction or a short side length direction of any one of the light emitting display panel, the substrate 100, and the base member 411.

According to another embodiment of the present disclosure, the length direction of each of the plurality of protrusion patterns 413a may be parallel to the second direction Y which intersects with the first direction X. For example, as shown in FIG. 6B, each of the plurality of protrusion patterns 413a extends long in the second direction Y and may be arranged in parallel along the first direction X.

According to another embodiment of the present disclosure, as shown in FIG. 6C, each of the plurality of protrusion patterns 413a may be arranged in parallel along each of the first direction X and the second direction Y and may have a quadrangular pyramid structure or a pyramid structure. For example, each of the plurality of protrusion patterns 413a according to another embodiment of the present disclosure may be implemented in a rectangular pyramid structure or a pyramid structure by the intersection between the plurality of protrusion patterns 413a extending long in the first direction X described in FIG. 6A and the plurality of protrusion patterns 413a extending long in the second direction Y described in FIG. 6B.

The lower surface (or bottom surface) of each of the plurality of protrusion patterns 413a may be disposed closer to the substrate 100 than the top surface (or top portion).

Each of the plurality of protrusion patterns 413a protrudes from the base member 411, and each of the plurality of protrusion patterns 413a may have the same material as the base member 411 or the same refractive index as the base member 411, but is not limited thereto. For example, the plurality of protrusion patterns 413a may be implemented by a refractive material layer coated on the second surface 400b of the base member 411. The refractive material layer may have the same refractive index as the base member 411, or may have the different refractive index from the base member 411.

Each of the plurality of recessed patterns 413b may be disposed between the plurality of protrusion patterns 413a. Each of the plurality of recessed patterns 413b may be disposed between the plurality of protrusion patterns 413a along at least one of the first direction X and the second direction Y according to the arrangement structure of the plurality of protrusion patterns 413a, as shown in FIGS. 6A to 6C. For example, each of the plurality of recessed patterns 413b may be a second refractive medium, a low refractive medium, a valley pattern, or a valley portion, but is not limited thereto.

The polarization member 500 according to an embodiment of the present disclosure may be coupled to the light guide portion 400 by using a coupling member (or a second transparent adhesive member) 550.

A first surface of the coupling member 550 may be coupled to the polarization member 500, and a second surface of the coupling member 550 may be coupled to the light refraction pattern portion 413 of the light guide portion 400. The second surface of the coupling member 550 may have a shape corresponding to the light refraction pattern portion 413.

The coupling member 550 may cover the entire light refraction pattern portion 413 of the light guide portion 400 or may be filled in the light refraction pattern portion 413. The coupling member 550 may be configured to be completely filled in each of the plurality of recessed patterns 413b without voids. For example, the coupling member 550 may be configured to completely filled in each of the plurality of recessed patterns 413b without voids and may completely surround each of the plurality of protrusion patterns 413a. For example, the first surface of the coupling member 550 may be spaced apart from each of the plurality of protrusion patterns 413a.

The coupling member 550 may have a refractive index which is different from the light guide portion 400 (or a light refraction pattern portion). The coupling member 550 according to an embodiment of the present disclosure may have a second refractive index which is less than the light guide portion 400 (or the light refraction pattern portion). Accordingly, each of the plurality of recessed patterns 413b filled with the coupling member 550 may implement the second refractive medium or the low refractive medium, but is not limited thereto.

The coupling member 550 according to an embodiment of the present disclosure may include acrylic resin, but is not limited thereto. For example, the acrylic resin may have a refractive index which is less than the light guide portion 400 by polymerization conditions as a polymer of acetone, cyanic acid and methacrylic acid methyl ester (methacrylic acid methyl).

The reflected light incident on the light guide portion 400 according to an embodiment of the present disclosure proceeds to the coupling member 550 having a relatively low refractive index in each of the plurality of protrusion patterns 413a having a relatively high refractive index, so that the reflected light may be dispersed by a color separation or an addition of a diffraction dispersion spectrum according to a difference in refractive angles for each wavelength in the interface (or refractive surface) between the protrusion pattern 413a and the coupling member 550. In particular, as the color dispersion according to the refraction angle for each wavelength increases in the interface (or refractive surface) between the protrusion pattern 413a and the coupling member 550, the color separation phenomenon between the short wavelength and the long wavelength may be maximized as the refraction angle of the short wavelength with respect to the long wavelength increases. Accordingly, the light guide portion 400 according to an embodiment of the present disclosure may reduce the dispersion spectrum intensity of the reflected light by the light extraction portion 131 through the difference in refractive indices of the plurality of protrusion patterns 413a with respect to the coupling member 550 or re-disperse the diffraction dispersion spectrum so as to greatly expand the size of the spectrum, and prevent or reduce the generation of rainbow patterns in the radial form through mixing between adjacent spectra, thereby reducing or minimizing the degradation of the black visibility characteristics caused by the reflected light of the light extraction portion 131. Therefore, the light emitting display device including the light guide portion 400 may realize real black in a non-driving or turning-off state.

According to an embodiment of the present disclosure, as shown in FIG. 6A, the light guide portion 400 including the plurality of protrusion patterns 413a having a longitudinal direction parallel to the first direction X re-disperses the diffraction dispersion spectrum of the reflected light by the light extraction portion 131 in the second direction Y so as to greatly expand the size of the spectrum, and suppresses or reduces the diffraction dispersion spectrum spread in the other directions other than the second direction Y, thereby suppressing the generation of rainbow pattern in the radial form through mixing between adjacent spectra along the second direction Y.

According to an embodiment of the present disclosure, as shown in FIG. 6B, the light guide portion 400 including the plurality of protrusion patterns 413a having a longitudinal direction parallel to the second direction Y re-disperses the diffraction dispersion spectrum of the reflected light by the light extraction portion 131 in the first direction X so as to greatly expand the size of the spectrum, and suppresses or reduces the diffraction dispersion spectrum spread in the other directions other than the first direction X, thereby suppressing the generation of rainbow pattern in the radial form through mixing between adjacent spectra along the first direction X.

According to an embodiment of the present disclosure, as shown in FIG. 6C, the light guide portion 400 including the plurality of protrusion patterns 413a disposed along each of the first direction X and the second direction Y re-disperses the diffraction dispersion spectrum of the reflected light by the light extraction portion 131 in each of the first direction X and the second direction Y so as to greatly expand the size of the spectrum, thereby suppressing or reducing the generation of rainbow pattern in the radial form through mixing between adjacent spectra along each of the first direction X and the second direction Y.

FIG. 7 is a cross-sectional view of the light guide portion and the polarization member shown in FIG. 2 according to another embodiment.

Referring to FIGS. 2 and 7, the light guide portion 400 according to another embodiment of the present disclosure may include a base member 411, a light refraction pattern portion 413, and a cover layer (or an overlay layer) 415.

Each of the base member 411 and the light refraction pattern portion 413 may be substantially the same as each of the base member 411 and the light refraction pattern portion 413 described in FIGS. 5 to 6C, and thus, like reference numerals refer to like elements and their repetitive descriptions may be omitted.

The cover layer 415 may cover the entire light refraction pattern portion 413 or may be filled in the light refraction pattern portion 413. The cover layer 415 may be formed to completely cover each of the plurality of protrusion patterns 413a and the plurality of recessed patterns 413b, thereby implementing a flat surface 400c over the light refraction pattern portion 413. For example, the cover layer 415 may be configured to be completely filled in each of the plurality of recessed patterns 413b without voids and to completely surround each of the plurality of protrusion patterns 413a. For example, the flat surface 400c of the cover layer 415 may be spaced apart from each of the plurality of protrusion patterns 413a, thereby preventing or protecting the damage of each of the plurality of protrusion patterns 413a from an external impact. For example, the cover layer 415 may be an overcoat layer, a planarization refractive layer, a pattern cover layer, a pattern planarization layer, or a pattern protection layer, but is not limited thereto.

The cover layer 415 may have a refractive index different from the light refraction pattern portion 413. The refractive index of the cover layer 415 may be less than the refractive index of the light refraction pattern portion 413. The cover layer 415 according to an embodiment of the present disclosure may have a second refractive index which is less than the refractive index of the plurality of protrusion patterns 413a. Accordingly, the cover layer 415 may implement the second refractive medium or the low refractive medium, but is not limited thereto.

The cover layer 415 according to an embodiment of the present disclosure may include acrylic resin, but is not limited thereto. For example, the acrylic resin may have a refractive index which is less than the protrusion patterns 413a by polymerization conditions as a polymer of acetone, cyanic acid and methacrylic acid methyl ester (methacrylic acid methyl).

The cover layer 415 according to an embodiment of the present disclosure may be coupled to the polarization member 500 by using the coupling member 550. The coupling member 550 is coupled to the flat surface 400c of the cover layer 415, thereby increasing the coupling force between the polarization member 500 and the light guide portion 400.

The coupling member 550 may include a pressure sensitive adhesive PSA, an optical clear adhesive OCA, or an optical clear resin OCR, but is not limited thereto.

The reflected light incident on the light guide portion 400 according to another embodiment of the present disclosure proceeds to the cover layer 415 having a relatively low refractive index in each of the plurality of protrusion patterns 413a having a relatively high refractive index, so that the reflected light may be dispersed by a color separation or an addition of a diffraction dispersion spectrum according to a difference in refractive angles for each wavelength in the interface (or refractive surface) between the protrusion pattern 413a and the cover layer 415. In particular, as the color dispersion according to the refraction angle for each wavelength increases in the interface (or refractive surface) between the protrusion pattern 413a and the cover layer 415, the color separation phenomenon between the short wavelength and the long wavelength may be maximized as the refraction angle of the short wavelength with respect to the long wavelength increases. Accordingly, the light guide portion 400 according to an embodiment of the present disclosure may reduce the dispersion spectrum intensity of the reflected light by the light extraction portion 131 through the difference in refractive indices between each of the plurality of protrusion patterns 413a and the cover layer 415 or re-disperse the diffraction dispersion spectrum so as to greatly expand the size of the spectrum, and prevent or reduce the generation of rainbow patterns in the radial form through mixing between adjacent spectra, thereby reducing or minimizing the degradation of the black visibility characteristics caused by the reflected light of the light extraction portion 131. Therefore, the light emitting display device including the light guide portion 400 may realize real black in a non-driving or turning-off state.

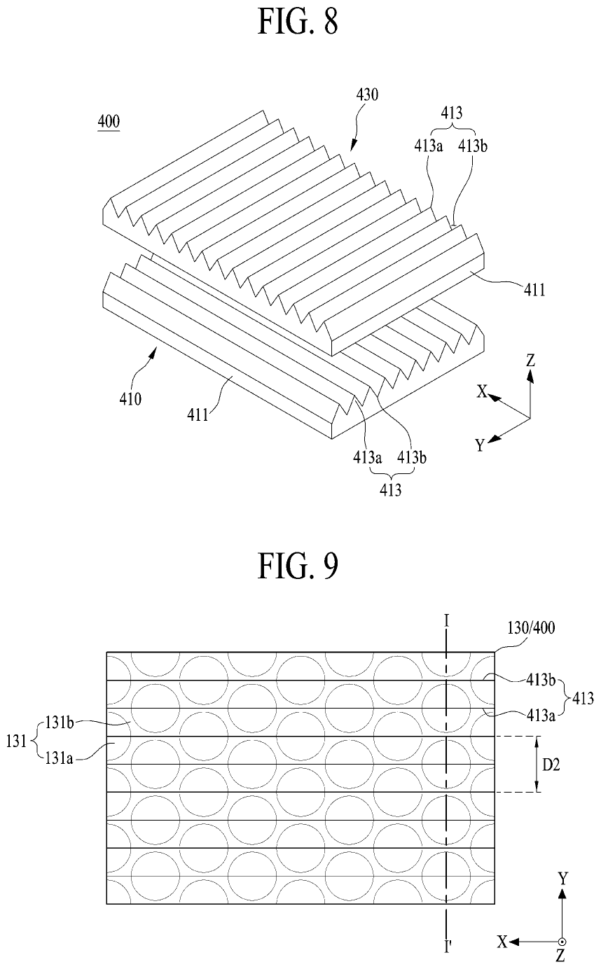

FIG. 8 is a view illustrating a light guide portion according to another embodiment of the present disclosure.

Referring to FIG. 8, the light guide portion 400 according to another embodiment of the present disclosure may include a first light guide member 410 and a second light guide member 430.

The first light guide member 410 may be a lower light guide portion. The first light guide member 410 according to an embodiment of the present disclosure may include a base member 411 and a light refraction pattern portion 413. Each of the base member 411 and the light refraction pattern portion 413 of the first light guide member 410 may be substantially the same as the base member 411 and the light refraction pattern portion 413 described in FIGS. 5 and 6A, and thus, like reference numerals refer to like elements and their repetitive descriptions may be omitted. The first light guide member 410 may suppress or reduce the diffraction dispersion spectrum spread in the second direction Y by re-dispersing the diffraction dispersion spectrum of the reflected light by the light extraction portion 131 in the first direction X through the light refraction pattern portion 413.

The second light guide member 430 may be disposed over the first light guide member 410. For example, the second light guide member 430 may be disposed between the first light guide member 410 and the polarization member 500. The second light guide member 430 may be an upper light guide portion. The second light guide member 430 according to an embodiment of the present disclosure may include a base member 411 and a light refraction pattern portion 413. Each of the base member 411 and the light refraction pattern portion 413 of the second light guide member 430 may be substantially the same as the base member 411 and the light refraction pattern portion 413 described in FIGS. 5 and 6A, and thus, like reference numerals refer to like elements and their repetitive descriptions may be omitted. The second light guide member 430 may suppress or minimize the diffraction dispersion spectrum spread in the first direction X by re-dispersing the diffraction dispersion spectrum firstly re-dispersed by the first light guide member 410 in the second direction Y.

The light guide portion 400 re-disperses the diffraction dispersion spectrum of the reflected light by the light extraction portion 131 in each of the first direction X and the second direction Y through the plurality of protrusion patterns 413a disposed at the first light guide member 410 and the plurality of protrusion patterns 413a disposed at the second light guide member 430 so as to greatly expand the size of the spectrum, wherein the first light guide member 410 and the second light guide member 430 intersect with each other, so that it is possible to suppress or reduce the generation of the rainbow pattern in the radial form through mixing between adjacent spectra.

Alternatively, the positions of the first light guide member 410 and the second light guide member 430 may be changed. For example, the second light guide member 430 may be disposed under the first light guide member 410. For example, the first light guide member 410 may be disposed between the second light guide member 430 and the polarization member 500. In this case, the light guide portion 400 re-disperses the diffraction dispersion spectrum of the reflected light by the light extraction portion 131 in each of the first direction X and the second direction Y through the plurality of protrusion patterns 413a disposed at the first light guide member 410 and the plurality of protrusion patterns 413a disposed at the second light guide member 430 so as to greatly expand the size of the spectrum, wherein the first light guide member 410 and the second light guide member 430 intersect with each other, so that it is possible to suppress or minimize the generation of the rainbow pattern in the radial form through mixing between adjacent spectra.

Additionally, each of the first light guide member 410 and the second light guide member 430 may further include a cover layer (or an overlay layer) covering (or overlaying) the light refraction pattern portion 413. The cover layer may be substantially the same as the cover layer 415 described in FIG. 7, the repetitive description thereof may be omitted.

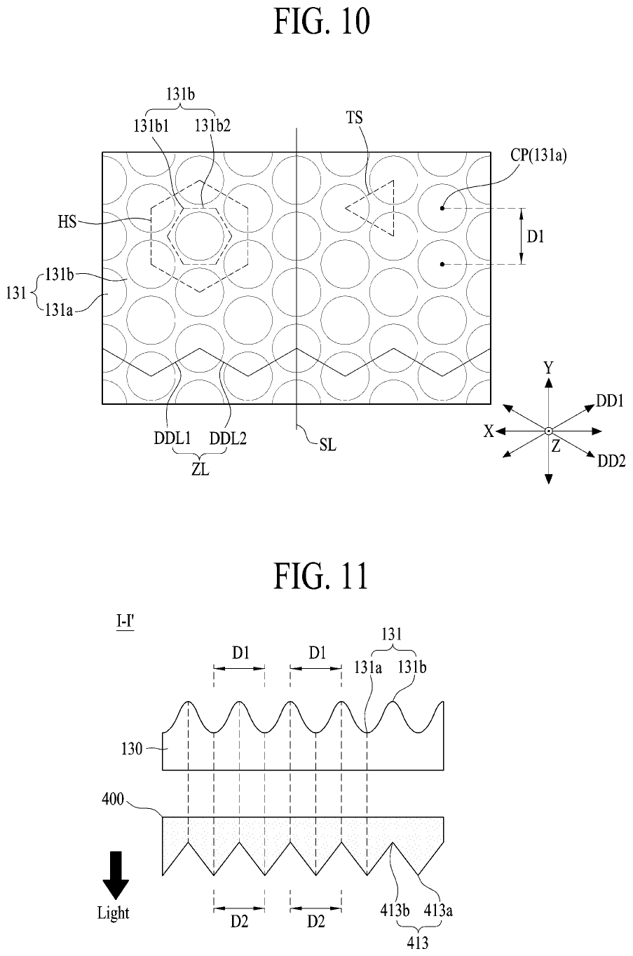

FIG. 9 is a view for explaining a light emitting display device according to another embodiment of the present disclosure, FIG. 10 is a plan view showing a light extraction portion of a planarization layer shown in FIG. 9 according to another embodiment of the present disclosure, and FIG. 11 is a cross-sectional view along I-I′ of FIG. 9 according to another embodiment of the present disclosure. FIG. 9 is a plan view illustrating an arrangement structure of the light extraction portion of the planarization layer and the light guide portion in the light emitting display device shown in FIG. 2.

Referring to FIGS. 9 to 11, in the light emitting display device according to another embodiment of the present disclosure, the light guide portion 400 may be configured to correspond to an arrangement structure (or shape) of a plurality of concave portions 131a or convex portions 131b disposed in the light extraction portion 131 of the planarization layer 130. For example, the plurality of concave portions 131a or the convex portions 131b disposed in the light extraction portion 131 may serve as a diffraction grating pattern according to the reflection diffraction grating rule (or equation), whereby the external reflected light by the light extraction portion 131 may generate the dispersion spectrum according to the reflection diffraction grating rule with respect to the concave portion 131a or the convex portion 131b according to double reflection in the concave portion 131a or the convex portion 131b. In order to suppress (or reduce) or re-disperse the dispersion spectrum generated in the concave portion 131a or the convex portion 131b, the light refraction pattern portion 413 of the light guide portion 400 may be disposed to correspond to or overlap the concave portion 131a or the convex portion 131b of the light extraction portion 131.

The light extraction portion 131 according to an embodiment of the present disclosure may include the plurality of concave portions 131a and convex portions 131b. Each of the plurality of concave portions 131a and the convex portions 131b is the same as described with reference to FIGS. 2 and 3, the repetitive description thereof may be omitted or will be briefly given.

Each of the plurality of concave portions 131a may be arranged in parallel to have a predetermined interval along the second direction Y, and may be alternately arranged along the first direction X. For example, a central portion CP of each of the plurality of concave portions 131a disposed along the second direction Y may be positioned or aligned in a straight line SL parallel to the second direction Y.

Each of the plurality of concave portions 131a may be disposed in parallel to have a predetermined interval along the first diagonal direction DD1 between the first direction X and the second direction Y. For example, the central portion CP of each of the plurality of concave portions 131a disposed along the first diagonal direction DD1 may be positioned or aligned in a first diagonal line DDL1 parallel to a first diagonal direction DD1. For example, an angle between the first direction X and the first diagonal direction DD1 may be 150 (or 30) degrees, and an angle between the second direction Y and the first diagonal direction DD1 may be 60 (or 120) degrees, but is not limited thereto.

Each of the plurality of concave portions 131a may be disposed in parallel to have a predetermined interval along a second diagonal direction DD2 crossing the first diagonal direction DD1. For example, the central portion CP of each of the plurality of concave portions 131a disposed along the second diagonal direction DD2 may be positioned or aligned in a second diagonal line DDL2 parallel to the second diagonal direction DD2. For example, the first diagonal direction DD1 and the second diagonal direction DD2 may be symmetrical with respect to the straight line SL that is parallel to the second direction Y. For example, an angle between the first direction X and the second diagonal direction DD2 may be 30 (or 150) degrees, and an angle between the second direction Y and the second diagonal direction DD2 may be 120 (or 60) degrees, but is not limited thereto.

The central portion CP of each of the plurality of concave portions 131a disposed along the first direction X may be positioned or aligned in a zigzag line ZL having a zigzag shape along the first direction X. For example, the central portion CP of each of the plurality of concave portions 131a disposed along the first direction X may be positioned or aligned in a zigzag line ZL in which the first diagonal line DDL1 and the second diagonal line DDL2 are alternately repeated. For example, the central portion CP of each of the plurality of concave portions 131a disposed in the even-numbered vertical lines parallel to the second direction Y may be disposed at the center portion between the plurality of concave portions 131a disposed in the adjacent odd-numbered vertical line along the first direction X. Thus, the light extraction portion 131 may include a larger number of concave portions 131a per unit area, thereby increasing the external extraction efficiency of the light emitted from the light emitting device layer.

According to an embodiment of the present disclosure, the central portion CP of each of the adjacent three concave portions 131a may be aligned to form a triangular shape TS. In addition, the central portion CP of each of the six concave portions 131a disposed around one concave portion 131a or surrounding one concave portion 131a may have a 6-angular shape HS. For example, each of the plurality of concave portions 131a may be disposed or arranged in two-dimensionally a honeycomb structure or a hexagonal structure.

A first distance (or pitch) D1 between the central portion CP of each of the plurality of concave portions 131a (for example, between two adjacent concave portions 131a) may be equal to each other. Here, the first distance D1 may be a distance (or a pitch) between the central portions CP of the two adjacent concave portions 131a. The first distance D1 may be the same as the first distance D1 between the adjacent two concave portions 131a along each of the second direction Y and the first and second diagonal directions DD1 and DD2.

The convex portion 131b may be implemented to individually surround each of the plurality of concave portions 131a. The convex portion 131b surrounding one concave portion 131a may two-dimensionally have a honeycomb shape, a hexagonal shape, or a circle shape.

A distance between the two convex portions 131b disposed between one concave portion 131a may be the same as the first distance D1 between the plurality of concave portions 131a. The distance between the two convex portions 131b disposed between one concave portion 131a along the second direction Y and the first and second diagonal directions DD1 and DD2 may be the same as the first distance D1 between the two adjacent concave portions 131a.

The convex portion 131b according to an embodiment of the present disclosure may further include a plurality of vertex portions 131b1 and a plurality of ridge portions 131b2.

Each of the plurality of vertex portions 131b1 may be disposed between the adjacent three concave portions 131a. Each of the plurality of vertex portions 131b1 may be a center portion between the adjacent three concave portions 131a. Each of the plurality of vertex portions 131b1 may be a portion at which the convex portions 131b surrounding each of the adjacent three concave portions 131a meet each other. For example, each of the plurality of vertex portions 131b1 may be a highest portion in the light extraction portion 131. Therefore, each of the plurality of vertex portions 131b1 may be referred to as a highest portion, a peak portion, a triple portion, a multipoint, or a triple point, or the like. For example, the convex portion 131b surrounding one concave portion 131a may include the five vertex portions 131b1.

Each of the plurality of ridge portions 131b2 may be disposed between the adjacent two vertex portions 131b1. Each of the plurality of ridge portions 131b2 may be disposed or connected between the adjacent two vertex portions 131b1, between the adjacent two concave portions 131a. Each of the plurality of ridge portions 131b2 may be a top portion of the convex portion 131b disposed between the adjacent two vertex portions 131b1. Therefore, each of the plurality of vertex portions 131b1 may be a portion at which the adjacent three ridge portions 131b2 are connected to one another. Vertex portions 131b1 and six ridge portions 131b2 near the concave portion 131a may two-dimensionally form a hexagonal shape HS. For example, each of the plurality of ridge portions 131b2 may be referred to as a connection portion or a peak connection portion, or the like, but is not limited thereto.

The pair of ridge portions 131b2 parallel to each other with one concave portion 131a disposed therebetween among the plurality of ridge portions 131b2 may be in parallel with the first direction X or may be parallel to the second direction Y. As shown in FIG. 10, the pair of ridge portions 131b2 parallel to each other with one concave portion 131a disposed therebetween among the plurality of ridge portions 131b2 may be parallel to the first direction X.

The light guide portion 400 according to another embodiment of the present disclosure re-disperses the dispersion spectrum of the reflected light reflected by the concave portion 131a and the convex portion 131b of the light extraction portion 131 in the first direction X, and suppresses the diffraction dispersion spectrum spread in the other direction other than the first direction X, thereby suppressing the generation of the rainbow pattern in the radial form.

According to an embodiment of the present disclosure, the light refraction pattern portion 413 of the light guide portion 400 may include a refractive pattern overlapped at least one of the concave portion 131a and the convex portion 131b of the light extraction portion 131.

The light refraction pattern portion 413 (or refractive pattern) according to an embodiment of the present disclosure may include a plurality of protrusion patterns 413a and a plurality of recessed patterns 413b.

Each of the plurality of protrusion patterns 413a extends long along the first direction X and may be disposed in parallel along the second direction Y crossing the first direction X. Each of the plurality of protrusion patterns 413a may be substantially the same as each of the plurality of protrusion patterns 413a described in FIG. 6A, and thus, the repetitive description thereof may be omitted.

Each of the plurality of protrusion patterns 413a may include a bottom surface (or bottom side), a vertex (or top portion), and an inclined surface (or oblique side). For example, each of the plurality of protrusion patterns 413a may be a prism. For example, with respect to the second direction Y, each of the plurality of protrusion patterns 413a may include a triangular cross-sectional structure such as a regular triangle or an isosceles triangle, or the like.

Each of the plurality of protrusion patterns 413a may be spaced or disposed to have a second distance (or pitch) D2. The distance between the adjacent two protrusion patterns 413a may have a second distance D2. For example, the distance between the vertices of the two protrusion patterns 413a adjacent along the second direction Y may have the second distance D2.

The second distance D2 between the plurality of protrusion patterns 413a according to an embodiment of the present disclosure may be the same as the first distance D1 between the plurality of concave portions 131a disposed in the light extraction portion 131 of the planarization layer 130. For example, the second distance D2 between the vertices of each of the two protrusion patterns 413a adjacent along the second direction Y may be equal to the first distance D1 between the plurality of concave portions 131a. For example, the first distance D1 and the second distance D2 may be the same or substantially the same within the process error range in the manufacturing process.

The second distance D2 between the plurality of protrusion patterns 413a may be the same as the width of the bottom surface of each of the plurality of protrusion patterns 413a. For example, with respect to the second direction Y, the bottom surface of each of the plurality of protrusion patterns 413a may have the same width as the second distance D2 between the plurality of protrusion patterns 413a. Accordingly, the width of the bottom surface of each of the plurality of protrusion patterns 413a may be the same as the first distance D1 between the plurality of concave portions 131a disposed in the light extraction portion 131 of the planarization layer 130.

Each of the plurality of protrusion patterns 413a according to an embodiment of the present disclosure may correspond to or overlap each of the plurality of concave portions 131a disposed in the light extraction portion 131 of the planarization layer 130. The vertex (or mountain portion or mountain central portion) of each of the plurality of protrusion patterns 413a may correspond to or overlap each of the plurality of concave portions 131a disposed in the light extraction portion 131. For example, the vertex line of each of the plurality of protrusion patterns 413a may overlap (e.g., is aligned with) the central portion CP in each of the plurality of concave portions 131a disposed along the first direction X and the convex portion 131b disposed between the plurality of concave portions 131a along the first direction X. For example, the vertex line of each of the plurality of protrusion patterns 413a may overlap the central line of each of the plurality of concave portions 131a parallel to the first direction X, and may overlap the convex portion 131b disposed between the adjacent four concave portions 131a along the first direction X. For example, in the convex portion 131b disposed between adjacent four concave portions 131a, the two vertex portions 131b1 disposed along the first direction X and the ridge portion 131b2 between the two vertex portions 131b1 may overlap the vertex line of the protrusion pattern 413a. Accordingly, each of the plurality of protrusion patterns 413a may reduce or minimize the generation of the rainbow pattern in the radial form through mixing between adjacent spectra along the second direction Y by re-dispersing the dispersion spectrum of the reflected light reflected from each of the plurality of concave portions 131a of the light extraction portion 131 in the second direction Y so as to greatly expand the size of the spectrum, and suppressing or reducing the diffraction dispersion spectrum spread in the different directions other than the second direction Y.

Each of the plurality of recessed patterns 413b may be disposed between the plurality of protrusion patterns 413a. Each of the plurality of recessed patterns 413b may be disposed in parallel with the first direction X. Each of the plurality of recessed patterns 413b may be covered (or overlaid) by the coupling member 550 described in FIG. 5 or may be covered (or overlaid) by the cover layer 415 described in FIG. 7.

Each of the plurality of recessed patterns 413b according to an embodiment of the present disclosure may correspond to (e.g., align with) or overlap the convex portion 131b disposed in the light extraction portion 131 of the planarization layer 130. Each of the plurality of recessed patterns 413b may correspond to or overlap each of the other concave portions 131a and the other convex portions 131b except for each of the concave portions 131a and the convex portions 131b overlapping each of the plurality of protrusion patterns 413a. The bottom surface (or bottom central portion, valley portion, or valley central portion) of each of the plurality of recessed patterns 413b may correspond to or overlap the convex portion 131b disposed in the light extraction portion 131. For example, the bottom surface of each of the plurality of recessed patterns 413b may overlap the central portion CP of the plurality of concave portions 131a disposed along the first direction X and the convex portion 131b disposed between the plurality of concave portions 131a along the first direction X. For example, the bottom surface of each of the plurality of recessed patterns 413b overlaps the central line of each of the plurality of concave portions 131a which are parallel to the first direction X, and may overlap the convex portion 131b disposed between the adjacent four concave portions 131a. For example, in the convex portion 131b disposed between the adjacent four concave portions 131a, the two vertex portions 131b1 disposed along the first direction X and the ridge portion 131b2 between the two vertex portions 131b1 may overlap the bottom surface of the recessed pattern 413b. Accordingly, each of the plurality of recessed patterns 413b may reduce or minimize the generation of the rainbow pattern in the radial form through mixing between adjacent spectra along the second direction Y by re-dispersing the dispersion spectrum of the reflected light reflected from the convex portion 131b of the light extraction portion 131 in the second direction Y so as to greatly expand the size of the spectrum, and suppressing or reducing the diffraction dispersion spectrum spread in the different directions other than the second direction Y.

As described above, the light emitting display device according to another embodiment of the present disclosure includes the light guide portion 400 having the plurality of protrusion patterns 413a and the plurality of recessed patterns 413b which respectively correspond to or overlap the plurality of concave portions 131a and convex portions 131b disposed in the light extraction portion 131 of the planarization layer 130 so that it is possible to suppress or reduce the generation of the rainbow pattern in the radial form through mixing between adjacent spectra along the second direction Y by re-dispersing the dispersion spectrum of the reflected light reflected from the light extraction portion 131 of the planarization layer 130 in the second direction Y through the use of the plurality of protrusion patterns 413a and the plurality of recessed patterns 413b so as to greatly expand the size of the spectrum, to thereby reduce the degradation of the black visibility characteristics caused by the reflected light by the light extraction portion 131.

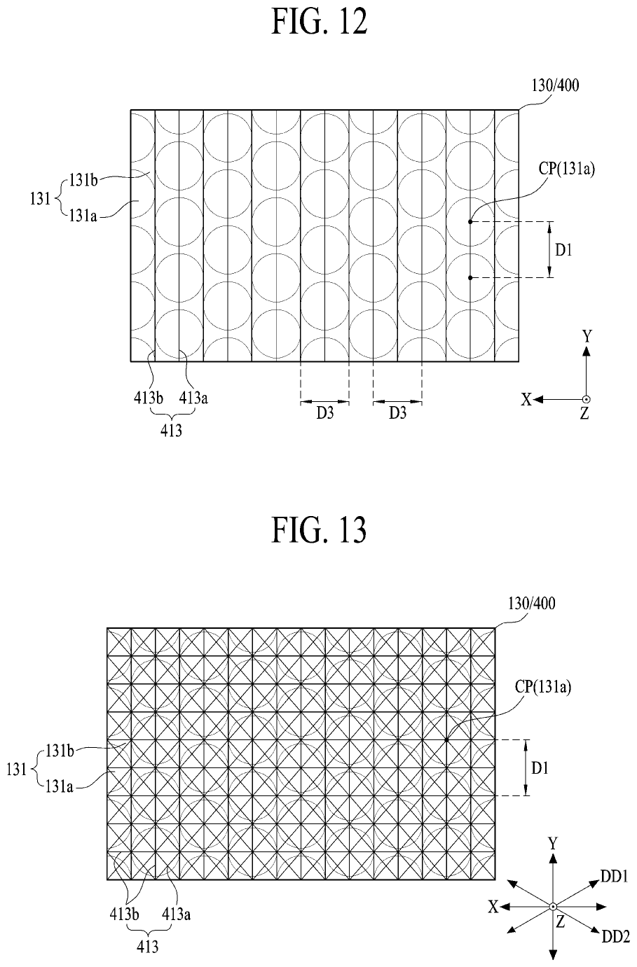

FIG. 12 illustrates a light emitting display device according to another embodiment of the present disclosure. FIG. 12 is obtained by changing the light guide portion shown in FIGS. 9 to 11. Accordingly, in the following description, descriptions of the other elements except for the light guide portion may be omitted or will be briefly given.

Referring to FIGS. 10 and 12, in the light emitting display device according to another embodiment of the present disclosure, a light extraction portion 131 disposed in a planarization layer 130 may be the same as the light extraction portion 131 described in FIGS. 9 to 11, and thus, the repetitive description thereof may be omitted

In the light emitting display device according to another embodiment of the present disclosure, the light guide portion 400 re-disperses the dispersion spectrum of the reflected light reflected by the concave portion 131a and the convex portion 131b of the light extraction portion 131 in the second direction Y, and suppresses the diffraction dispersion spectrum spread in the other direction other than the second direction Y, thereby suppressing the generation of the rainbow pattern in the radial form.

According to an embodiment of the present disclosure, a light refraction pattern portion 413 of the light guide portion 400 may include a plurality of protrusion patterns 413a and a plurality of recessed patterns 413b.

Each of the plurality of protrusion patterns 413a extends along the second direction Y and may be disposed in parallel along the first direction X. Each of the plurality of protrusion patterns 413a may be substantially the same as each of the plurality of protrusion patterns 413a described in FIG. 6B, and thus, the repetitive description thereof may be omitted.

Each of the plurality of protrusion patterns 413a according to an embodiment of the present disclosure may be spaced or disposed to have a third distance (or pitch) D3. The distance between the adjacent two protrusion patterns 413a may have a third distance D3. For example, the distance between the vertices of the two protrusion patterns 413a adjacent along the first direction X may have the third distance D3.

The third distance D3 between the plurality of protrusion patterns 413a according to an embodiment of the present disclosure may be smaller than the first distance D1 between the plurality of concave portions 131a disposed in the light extraction portion 131 of the planarization layer 130. For example, the third distance D3 between the vertices of the two protrusion patterns 413a adjacent along the first direction X may be smaller than the first distance D1 between the plurality of concave portions 131a.

Each of the plurality of protrusion patterns 413a according to an embodiment of the present disclosure may correspond to (e.g., align with) or overlap each of the plurality of concave portions 131a disposed in the light extraction portion 131 of the planarization layer 130. The vertex (or mountain portion or mountain central portion) of each of the plurality of protrusion patterns 413a may correspond to (e.g., align with) or overlap each of the plurality of concave portions 131a disposed in the light extraction portion 131. For example, the vertex line of each of the plurality of protrusion patterns 413a may overlap the central portion CP in each of the plurality of concave portions 131a disposed along the second direction Y and the convex portion 131b disposed between the plurality of concave portions 131a along the second direction Y. For example, the vertex line of each of the plurality of protrusion patterns 413a may overlap the central line of each of the plurality of concave portions 131a parallel to the second direction Y, and may overlap the convex portion 131b disposed between the adjacent four concave portions 131a along the second direction Y. For example, the vertex line of each of the plurality of protrusion patterns 413a may be disposed in a direction crossing the ridge portion 131b2 of the convex portion 131b parallel to the first direction X. Accordingly, each of the plurality of protrusion patterns 413a may reduce or minimize the generation of the rainbow pattern in the radial form through mixing between adjacent spectra along the first direction X by re-dispersing the dispersion spectrum of the reflected light reflected from each of the plurality of concave portions 131a of the light extraction portion 131 in the first direction X so as to greatly expand the size of the spectrum, and suppressing or minimizing the diffraction dispersion spectrum spread in the different directions other than the first direction X.

Each of the plurality of recessed patterns 413b may be disposed between the plurality of protrusion patterns 413a. Each of the plurality of recessed patterns 413b may be disposed in parallel with the second direction Y. Each of the plurality of recessed patterns 413b may be covered (or overlaid) by the coupling member 550 described in FIG. 5 or may be covered (or overlaid) by the cover layer 415 described in FIG. 7.

Each of the plurality of recessed patterns 413b according to an embodiment of the present disclosure may correspond to or overlap the convex portion 131b disposed in the light extraction portion 131 of the planarization layer 130. The bottom surface (or bottom central portion, valley portion, or valley central portion) of each of the plurality of recessed patterns 413b may correspond to or overlap the convex portion 131b disposed in the light extraction portion 131. For example, the bottom surface of each of the plurality of recessed patterns 413b may overlap a convex portion 131b between adjacent concave portions 131a which are staggered disposed in a zigzag shape along the second direction Y. For example, the bottom surface of each of the plurality of recessed patterns 413b may overlap only the convex portion 131b along the second direction Y and not overlap the one or more concave portions 131a. For example, each of the plurality of recessed patterns 413b is disposed between the plurality of protrusion patterns 413a disposed to have a third distance D3 that is less than a first distance D1 between the adjacent two concave portions 131a, so that the bottom surface of each of the plurality of recessed patterns 413b may overlap the convex portion 131b along the second direction Y without overlapping the one or more concave portions 131a. Accordingly, each of the plurality of recessed patterns 413b may reduce or minimize the generation of the rainbow pattern in the radial form through mixing between adjacent spectra along the first direction X by re-dispersing the dispersion spectrum of the reflected light reflected from the convex portion 131b of the light extraction portion 131 in the first direction X so as to greatly expand the size of the spectrum, and suppressing or minimizing the diffraction dispersion spectrum spread in the different directions other than the first direction X.

As described above, the light emitting display device according to another embodiment of the present disclosure includes the light guide portion 400 having the plurality of protrusion patterns 413a and the plurality of recessed patterns 413b which respectively correspond to (e.g., align with) or overlap the plurality of concave portions 131a and convex portions 131b disposed in the light extraction portion 131 of the planarization layer 130 so that it is possible to suppress or minimize the generation of the rainbow pattern in the radial form through mixing between adjacent spectra along the first direction X by re-dispersing the dispersion spectrum of the reflected light reflected from the light extraction portion 131 of the planarization layer 130 in the first direction X through the use of the plurality of protrusion patterns 413a and the plurality of recessed patterns 413b so as to greatly expand the size of the spectrum, to thereby reduce the degradation of the black visibility characteristics caused by the reflected light by the light extraction portion 131.

FIG. 13 illustrates a light emitting display device according to another embodiment of the present disclosure. FIG. 13 is obtained by changing the light guide portion shown in FIGS. 9 to 11. Accordingly, in the following description, descriptions of the other elements except for the light guide portion may be omitted or will be briefly given.

Referring to FIGS. 10 and 13, in the light emitting display device according to another embodiment of the present disclosure, a light extraction portion 131 disposed in a planarization layer 130 may be the same as the light extraction portion 131 described in FIGS. 9 to 11, and thus, the repetitive description thereof may be omitted.

In the light emitting display device according to another embodiment of the present disclosure, the light guide portion 400 re-disperses the dispersion spectrum of the reflected light reflected by the concave portion 131a and the convex portion 131b of the light extraction portion 131 in the first direction X and the second direction Y so as to greatly expand the size of the spectrum, thereby suppressing the generation of the rainbow pattern in the radial form through mixing between adjacent spectra along the first direction X and the second direction Y.

According to an embodiment of the present disclosure, a light refraction pattern portion 413 of a light guide portion 400 may include a plurality of protrusion patterns 413a and a plurality of recessed patterns 413b.

Each of the plurality of protrusion patterns 413a may be disposed in parallel along the first direction X and the second direction Y. Each of the plurality of protrusion patterns 413a may be disposed in parallel along the first direction X and the second direction Y, and may have a quadrangle pyramid structure or a pyramid structure. According to an embodiment of the present disclosure, each of the plurality of protrusion patterns 413a may be substantially the same as each of the plurality of protrusion patterns 413a described in FIG. 6C, and thus, the repetitive description thereof may be omitted. According to another embodiment of the present disclosure, each of the plurality of protrusion patterns 413a may be implemented in the quadrangle pyramid structure or the pyramid structure by the intersection between the plurality of protrusion patterns 413a extending long in the first direction X described in FIG. 9 and the plurality of protrusion patterns 413a extending long in the second direction Y described in FIG. 12.

Each of the plurality of protrusion patterns 413a according to an embodiment of the present disclosure may correspond to (e.g., align with) or overlap each of the plurality of concave portions 131a disposed in the light extraction portion 131 of the planarization layer 130. The vertex (or mountain portion or mountain central portion) of each of the plurality of protrusion patterns 413a may correspond to (e.g., align with) or overlap each of the plurality of concave portions 131a disposed in the light extraction portion 131. For example, the vertex of each of the adjacent four protrusion patterns 413a may overlap one concave portion 131a. The vertex of each of the plurality of protrusion patterns 413a may overlap the concave portion 131a and without overlapping the one or more convex portions 131b. Accordingly, each of the plurality of protrusion patterns 413a may reduce or minimize the generation of the rainbow pattern in the radial form through mixing between adjacent spectra along the first direction X and the second direction Y by re-dispersing the dispersion spectrum of the reflected light reflected from each of the plurality of concave portion 131a of the light extraction portion 131 in the first direction X and the second direction Y so as to greatly expand the size of the spectrum.

Each of the plurality of recessed patterns 413b may be disposed between the plurality of protrusion patterns 413a. Each of the plurality of recessed patterns 413b may be disposed in parallel with each of the first direction X and the second direction Y. The plurality of recessed patterns 413b may be disposed in a lattice form. Each of the plurality of recessed patterns 413b may be covered (or overlaid) by the coupling member 550 described in FIG. 5 or may be covered (or overlaid) by the cover layer 415 described in FIG. 7.

Each of the plurality of recessed patterns 413b according to an embodiment of the present disclosure may correspond to (e.g., align with) or overlap the convex portion 131b disposed in the light extraction portion 131 of the planarization layer 130. The bottom surface (or bottom central portion, valley portion, or valley central portion) of each of the plurality of recessed patterns 413b may correspond to (e.g., align with) or overlap the convex portion 131b disposed in the light extraction portion 131. For example, the bottom surface of each of the plurality of recessed patterns 413b may overlap the central portion of each of the plurality of concave portions 131a and the convex portion 131b along each of the first direction X and the second direction Y. Some of the recessed patterns 413b, which are parallel to the second direction Y, overlap only the convex portion 131b, and the remaining of the recessed patterns 413b may overlap the central portion of each of the plurality of concave portions 131a and the convex portion 131b. For example, in case of the light refraction pattern portion 413 shown in FIG. 13, among the plurality of recessed patterns 413b arranged in parallel with each other along the first direction X, the odd-numbered recessed patterns 413b may overlap only the convex portion 131b, and the even-numbered recessed patterns 431b may overlap each of the center portions of the plurality of concave portions 131a and the convex portion 131b. Accordingly, each of the plurality of recessed patterns 413b may reduce or minimize the generation of the rainbow pattern in the radial form through mixing between adjacent spectra along the first direction X and the second direction Y by re-dispersing the dispersion spectrum of the reflected light reflected from each of the plurality of concave portion 131a of the light extraction portion 131 in the first direction X and the second direction Y so as to greatly expand the size of the spectrum.

As described above, the light emitting display device according to another embodiment of the present disclosure includes the light guide portion 400 having the plurality of protrusion patterns 413a and the plurality of recessed patterns 413b which respectively correspond to (e.g., align with) or overlap the plurality of concave portions 131a and convex portions 131b disposed in the light extraction portion 131 of the planarization layer 130 so that it is possible to suppress or minimize the generation of the rainbow pattern in the radial form through mixing between adjacent spectra along the first direction X and the second direction Y by re-dispersing the dispersion spectrum of the reflected light reflected from the light extraction portion 131 of the planarization layer 130 in the first direction X and the second direction Y through the use of the plurality of protrusion patterns 413a and the plurality of recessed patterns 413b so as to greatly expand the size of the spectrum, to thereby reduce the degradation of the black visibility characteristics caused by the reflected light by the light extraction portion 131.

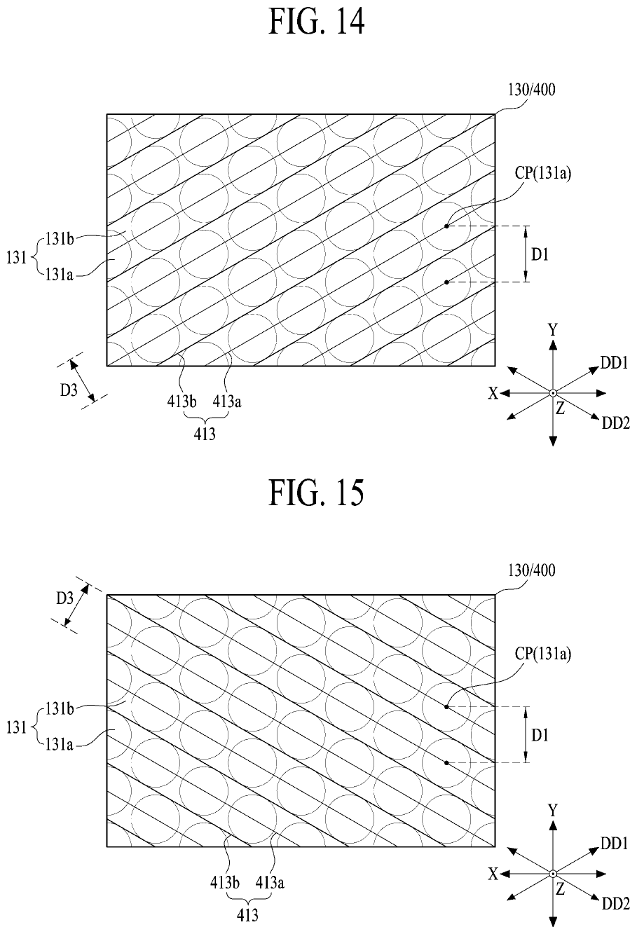

FIG. 14 illustrates a light emitting display device according to another embodiment of the present disclosure. FIG. 14 is obtained by changing the light guide portion shown in FIGS. 9 to 11. Accordingly, in the following description, descriptions of the other elements except for the light guide portion may be omitted or will be briefly given.

Referring to FIGS. 10 and 14, in the light emitting display device according to another embodiment of the present disclosure, a light extraction portion 131 disposed in a planarization layer 130 may be the same as the light extraction portion 131 described in FIGS. 9 to 11, and thus, the repetitive description thereof may be omitted.

Each of a plurality of protrusion patterns 413a extends long in a first diagonal direction DD1 between the first direction X and the second direction Y, and may be arranged in parallel along a second diagonal direction DD2. Each of the plurality of protrusion patterns 413a may be substantially the same as the plurality of protrusion patterns 413a described in FIG. 12, except that each of the plurality of protrusion patterns 413a extends long in the first diagonal direction DD1 and is disposed in parallel along the second diagonal direction DD2, and thus, the repetitive description thereof may be omitted or will be briefly given.

Each of the plurality of protrusion patterns 413a according to an embodiment of the present disclosure may correspond to (e.g., align with) or overlap each of a plurality of concave portions 131a disposed in a light extraction portion 131 of a planarization layer 130. A vertex (or mountain portion or mountain central portion) of each of the plurality of protrusion patterns 413a may correspond to (e.g., align with) or overlap each of the plurality of concave portions 131a disposed in the light extraction portion 131. For example, a vertex line of each of the plurality of protrusion patterns 413a may overlap a central portion CP of the plurality of concave portions 131a disposed along the first diagonal direction DD1 and a convex portion 131b disposed between the plurality of concave portions 131a along the second direction Y. Accordingly, each of the plurality of protrusion patterns 413a may suppress or minimize the generation of the rainbow pattern in a radial form through mixing between adjacent spectra along the second diagonal direction DD2 by re-dispersing the dispersion spectrum of the reflected light reflected from each of the plurality of concave portions 131a of the light extraction portion 131 in the second diagonal direction DD2 so as to greatly expand the size of spectrum, and suppressing or minimizing the diffraction dispersion spectrum spread in the other directions other than the second diagonal direction DD2.

Each of a plurality of recessed patterns 413b may be disposed between the plurality of protrusion patterns 413a. Each of the plurality of recessed patterns 413b may be disposed in parallel with the first diagonal direction DD1. Each of the plurality of recessed patterns 413b may be covered (or overlaid) by a coupling member 550, as shown in FIG. 5, or may be covered (or overlaid) by a cover layer 415 as shown in FIG. 7.

Each of the plurality of recessed patterns 413b according to an embodiment of the present disclosure may correspond to (e.g., align with) or overlap the convex portion 131b disposed in the light extraction portion 131 of the planarization layer 130. The bottom surface (or bottom central portion, valley portion, or valley central portion) of each of the plurality of recessed patterns 413b may correspond to (e.g., align with) or overlap the convex portion 131b disposed in the light extraction portion 131. For example, the bottom surface of each of the plurality of recessed patterns 413b may overlap the convex portion 131b along the first diagonal direction DD1 and without overlapping the one or more concave portions 131a. Accordingly, each of the plurality of recessed patterns 413b may greatly expand the size of the spectrum by re-dispersing the dispersion spectrum of the reflected light reflected from the convex portion 131b of the light extraction portion 131 in the second diagonal direction DD2, and may suppress or minimize the diffraction dispersion spectrum spread in the other directions other than the second diagonal direction DD2, to thereby suppress or minimize the generation of the rainbow pattern in the radial form through mixing between adjacent spectra along the second diagonal direction DD2.

Accordingly, the light emitting display device according to another embodiment of the present disclosure includes the light guide portion 400 having the plurality of protrusion patterns 413a and the plurality of recessed patterns 413b which respectively correspond to or overlap the plurality of concave portions 131a and convex portions 131b disposed in the light extraction portion 131 of the planarization layer 130 so that it is possible to suppress or minimize the generation of the rainbow pattern in the radial form through mixing between adjacent spectra along the second diagonal direction DD2 by re-dispersing the dispersion spectrum of the reflected light reflected from the light extraction portion 131 of the planarization layer 130 to the second diagonal direction DD2 through the use of the plurality of protrusion patterns 413a and the plurality of recessed patterns 413b so as to greatly expand the size of the spectrum, to thereby reduce the degradation of the black visibility characteristics caused by the reflected light by the light extraction portion 131.

FIG. 15 illustrates a light emitting display device according to another embodiment of the present disclosure. FIG. 15 is obtained by changing the light guide portion shown in FIGS. 9 to 11. Accordingly, in the following description, descriptions of the other elements except for the light guide portion may be omitted or will be briefly given.

Referring to FIGS. 10 and 15, in the light emitting display device according to another embodiment of the present disclosure, a light extraction portion 131 disposed in a planarization layer 130 may be the same as the light extraction portion 131 described in FIGS. 9 to 11, and thus, the repetitive description thereof may be omitted.

Each of a plurality of protrusion patterns 413a extends along in a second diagonal direction DD2 between the first direction X and the second direction Y, and may be arranged in parallel along a first diagonal direction DD1. Each of the plurality of protrusion patterns 413a may be substantially the same as the plurality of protrusion patterns 413a described in FIG. 14, except that each of the plurality of protrusion patterns 413a extends along in the second diagonal direction DD2 and is disposed in parallel along the first diagonal direction DD1, and thus, the repetitive description thereof may be omitted or will be briefly given.

Each of the plurality of protrusion patterns 413a according to an embodiment of the present disclosure may correspond to (e.g., align with) or overlap each of a plurality of concave portions 131a disposed in a light extraction portion 131 of a planarization layer 130. A vertex (or mountain portion or mountain central portion) of each of the plurality of protrusion patterns 413a may correspond to (e.g., align with) or overlap each of the plurality of concave portions 131a disposed in the light extraction portion 131. For example, a vertex line of each of the plurality of protrusion patterns 413a may overlap a central portion CP of the plurality of concave portions 131a disposed along the second diagonal direction DD2 and a convex portion 131b disposed between the plurality of concave portions 131a along the second direction Y. Accordingly, each of the plurality of protrusion patterns 413a may suppress or minimize the generation of the rainbow pattern in a radial form through mixing between adjacent spectra along the first diagonal direction DD1 by re-dispersing the dispersion spectrum of the reflected light reflected from each of the plurality of concave portions 131a of the light extraction portion 131 in the first diagonal direction DD1 so as to greatly expand the size of spectrum, and suppressing or minimizing the diffraction dispersion spectrum spread in the other directions other than the first diagonal direction DD1.

Each of a plurality of recessed patterns 413b may be disposed between the plurality of protrusion patterns 413a. Each of the plurality of recessed patterns 413b may be disposed in parallel with the second diagonal direction DD2. Each of the plurality of recessed patterns 413b may be covered (or overlaid) by a coupling member 550, as shown in FIG. 5, or may be covered (or overlaid) by a cover layer 415 as shown in FIG. 7.

Each of the plurality of recessed patterns 413b according to an embodiment of the present disclosure may correspond to (e.g., align with) or overlap the convex portion 131b disposed in the light extraction portion 131 of the planarization layer 130. The bottom surface (or bottom central portion, valley portion, or valley central portion) of each of the plurality of recessed patterns 413b may correspond to or overlap the convex portion 131b disposed in the light extraction portion 131. For example, the bottom surface of each of the plurality of recessed patterns 413b may overlap the convex portion 131b along the second diagonal direction DD2 without overlapping the one or more concave portions 131a. Accordingly, each of the plurality of recessed patterns 413b greatly expands the size of the spectrum by re-dispersing the dispersion spectrum of the reflected light reflected from the convex portion 131b of the light extraction portion 131 in the first diagonal direction DD1, and suppresses or minimizes the diffraction dispersion spectrum spread in the other directions other than the first diagonal direction DD1, to thereby suppress or minimize the generation of the rainbow pattern in the radial form through mixing between adjacent spectra along the first diagonal direction DD1.

As described above, the light emitting display device according to another embodiment of the present disclosure includes the light guide portion 400 having the plurality of protrusion patterns 413a and the plurality of recessed patterns 413b which respectively correspond to or overlap the plurality of concave portions 131a and convex portions 131b disposed in the light extraction portion 131 of the planarization layer 130 so that it is possible to suppress or minimize the generation of the rainbow pattern in the radial form through mixing between adjacent spectra along the first diagonal direction DD1 by re-dispersing the dispersion spectrum of the reflected light reflected from the light extraction portion 131 of the planarization layer 130 to the first diagonal direction DD1 through the use of the plurality of protrusion patterns 413a and the plurality of recessed patterns 413b so as to greatly expand the size of the spectrum, to thereby reduce the degradation of the black visibility characteristics caused by the reflected light by the light extraction portion 131.

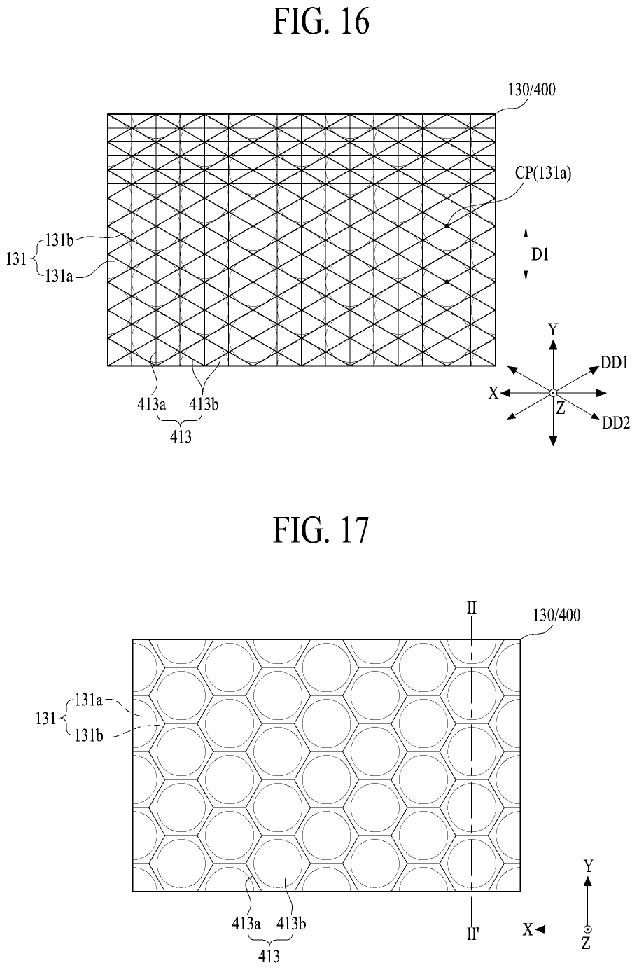

FIG. 16 illustrates a light emitting display device according to another embodiment of the present disclosure. FIG. 16 is obtained by changing the light guide portion shown in FIGS. 9 to 11. Accordingly, in the following description, descriptions of the other elements except for the light guide portion may be omitted or will be briefly given.

Referring to FIGS. 10 and 16, in the light emitting display device according to another embodiment of the present disclosure, a light extraction portion 131 disposed in a planarization layer 130 may be the same as the light extraction portion 131 described in FIGS. 9 to 11, and thus, the repetitive description thereof may be omitted.

In the light emitting display device according to another embodiment of the present disclosure, the light guide portion 400 re-disperses the dispersion spectrum of the reflected light reflected by a concave portion 131a and a convex portion 131b of the light extraction portion 131 to a first diagonal direction DD1 and a second diagonal direction DD2 so as to greatly expand the size of the spectrum, thereby suppressing or reducing the generation of the rainbow pattern in a radial form through mixing between adjacent spectra of the first diagonal direction DD1 and the second diagonal direction DD2.

According to an embodiment of the present disclosure, a light refraction pattern portion 413 of the light guide portion 400 may include a plurality of protrusion patterns 413a and a plurality of recessed patterns 413b.

Each of the plurality of protrusion patterns 413a may be disposed in parallel along the first diagonal direction DD1 and the second diagonal direction DD2. Each of the plurality of protrusion patterns 413a may be disposed in parallel along the first diagonal direction DD1 and the second diagonal direction DD2, and may have a quadrangle pyramid structure, and may have a rhombus structure in two-dimensional structure. According to an embodiment of the present disclosure, except that each of the plurality of protrusion patterns 413a has the rhombus structure in two-dimensional structure, the plurality of protrusion patterns 413a may be substantially the same as the plurality of protrusion patterns 413a described in FIG. 6C, and thus the repetitive description thereof may be omitted or will be briefly given. According to another embodiment of the present disclosure, each of the plurality of protrusion patterns 413a may be implemented in the quadrangle pyramid structure by the intersection between the plurality of protrusion patterns 413a extending long in the first diagonal direction DD1 described in FIG. 14 and the plurality of protrusion patterns 413a extending long in the second diagonal direction DD2 described in FIG. 15.

Each of the plurality of protrusion patterns 413a according to one embodiment of the present disclosure may correspond to (e.g., align with) or overlap each of the plurality of concave portions 131a and the convex portions 131b disposed in the light extraction portion 131 of the planarization layer 130. A vertex (or mountain portion or mountain central portion) of the protrusion pattern 413a disposed along the first direction X among the plurality of protrusion patterns 413a may correspond to (e.g., align with) or overlap each of the plurality of concave portions 131a disposed in the light extraction portion 131. A vertex (or mountain portion or mountain central portion) of the protrusion pattern 413a disposed along the second direction Y among the plurality of protrusion patterns 413a may correspond to or overlap the convex portion 131b. Therefore, each of the plurality of protrusion patterns 413a may greatly expand the size of the spectrum by re-dispersing the dispersion spectrum of the reflected light reflected from the plurality of concave portions 131a and the convex portion 131b of the light extraction portion 131 in the first diagonal direction DD1 and the second diagonal direction DD2, so that it is possible to suppress or minimize the generation of the rainbow pattern in a radial form through mixing between adjacent spectra of the first diagonal direction DD1 and the second diagonal direction DD2.

Each of the plurality of recessed patterns 413b may be disposed between the plurality of protrusion patterns 413a. Each of the plurality of recessed patterns 413b may be disposed in parallel with each of the first diagonal direction DD1 and the second diagonal direction DD2. Each of the plurality of recessed patterns 413b may be disposed in a lattice type obtained by the intersection between a plurality of first diagonal lines parallel to the first diagonal direction DD1 and a plurality of second diagonal lines parallel to the second diagonal direction DD2. Each of the plurality of recessed patterns 413b may be covered (or overlaid) by the coupling member 550, as shown in FIG. 5, or covered (or overlaid) by the cover layer 415 shown in FIG. 7.

Each of the plurality of recessed patterns 413b according to the embodiment of the present disclosure may correspond to (e.g., align with) or overlap each of the plurality of concave portions 131a and the convex portions 131b disposed in the light extraction portion 131 of the planarization layer 130. The bottom surface (or bottom central portion, valley portion, or valley central portion) of each of the plurality of recessed patterns 413b may correspond to (e.g., align with) or overlap each of the plurality of concave portions 131a and the convex portions 131b disposed in the light extraction portion 131. For example, the bottom surface of each of the plurality of recessed patterns 413b may overlap each of the central portion of each of the plurality of concave portions 131a and the convex portion 131b along the first diagonal direction DD1 and the second diagonal direction DD2. Some of the recessed patterns 413b parallel to the first diagonal direction DD1 or the second diagonal direction DD2 may overlap the convex portion 131b, and the remaining of the recessed patterns 413b may overlap each of the central portion of each of the plurality of concave portions 131a and the convex portion 131b. For example, in case of the light refraction pattern portion 413 shown in FIG. 16, among the plurality of recessed patterns 413b disposed in parallel with each other along the first diagonal direction DD1, the odd-numbered recessed patterns 413b may overlap the convex portion 131b, and the even-numbered recessed patterns 413b may overlap each of the central portions of the plurality of concave portions 131a and the convex portion 131b. Also, in case of the light refraction pattern portion 413 shown in FIG. 16, among the plurality of recessed patterns 413b disposed in parallel with each other along the second diagonal direction DD2, the odd-numbered recessed patterns 413b may overlap only the convex portion 131b, and the even-numbered recessed patterns 413b may overlap each of the central portions of the plurality of concave portions 131a and the convex portion 131b. Accordingly, each of the plurality of recessed patterns 413b may greatly expand the size of the spectrum by re-dispersing the dispersion spectrum of the reflected light reflected from each of the convex portion 131b and the plurality of concave portions 131a of the light extraction portion 131 in the first diagonal direction DD1 and the second diagonal direction DD2, thereby suppressing or minimizing the generation of the rainbow pattern in the radial form through mixing between adjacent spectra of the first diagonal direction DD1 and the second diagonal direction DD2.

As described above, the light emitting display device according to another embodiment of the present disclosure includes the light guide portion 400 having the plurality of protrusion patterns 413a and the plurality of recessed patterns 413b which respectively correspond to or overlap the plurality of concave portions 131a and convex portions 131b disposed in the light extraction portion 131 of the planarization layer 130 so that it is possible to suppress or reduce the generation of the rainbow pattern in the radial form through mixing between adjacent spectra along the first diagonal direction DD1 and the second diagonal direction DD2 by re-dispersing the dispersion spectrum of the reflected light reflected from the light extraction portion 131 of the planarization layer 130 in the first diagonal direction DD1 and the second diagonal direction DD2 through the use of the plurality of protrusion patterns 413a and the plurality of recessed patterns 413b so as to greatly expand the size of the spectrum, to thereby reduce the degradation of the black visibility characteristics caused by the reflected light by the light extraction portion 131.

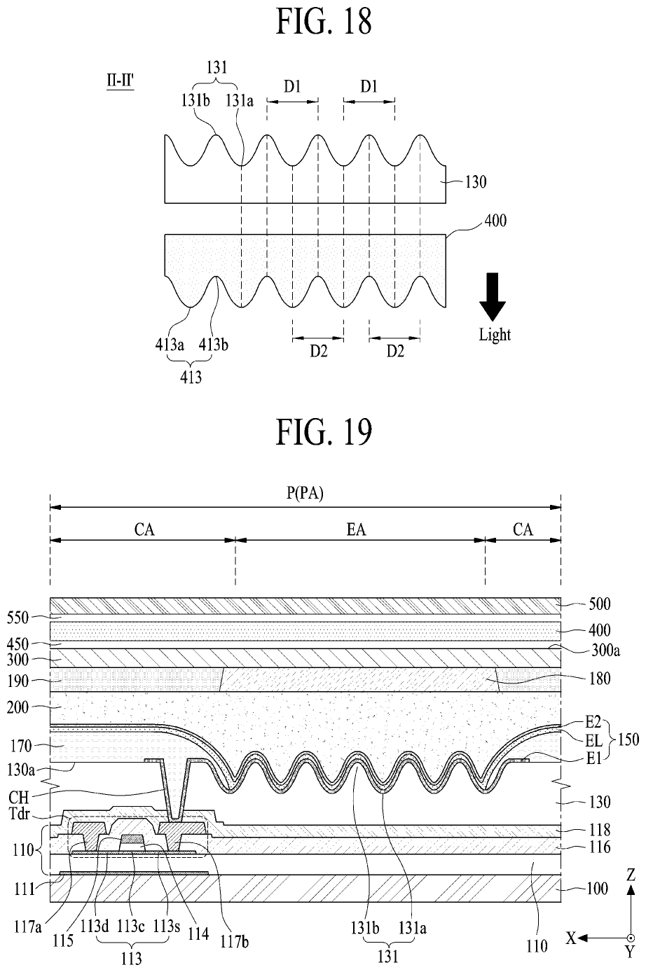

FIG. 17 illustrates a light emitting display device according to another embodiment of the present disclosure, and FIG. 18 is a cross-sectional view along II-II′ of FIG. 17 according to the other embodiment of the present disclosure. FIGS. 17 and 18 are obtained by changing the light guide portions shown in FIGS. 9 to 11. Accordingly, in the following description, descriptions of the other elements except for the light guide portion may be omitted or will be briefly given.

Referring to FIGS. 10, 17 and 18, in the light emitting display device according to another embodiment of the present disclosure, a light extraction portion 131 disposed in a planarization layer 130 may be the same as the light extraction portion 131 described in FIGS. 9 to 11, and thus, the repetitive description thereof may be omitted.

In the light emitting display device according to another embodiment of the present disclosure, the light guide portion 400 re-disperses the dispersion spectrum of the reflected light reflected by concave portion 131a and convex portion 131b of a light extraction portion 131 in a radial form so as to greatly expand the size of the spectrum, thereby suppressing or reducing the occurrence of the rainbow pattern in a radial form through mixing between adjacent spectra.

According to an embodiment of the present disclosure, a light refraction pattern portion 413 of the light guide portion 400 may include a plurality of protrusion patterns 413a and a plurality of recessed patterns 413b.

Each of the plurality of protrusion patterns 413a may have a shape corresponding to or the same as the concave portion 131a of the light extraction portion 131. Each of the plurality of protrusion patterns 413a may be disposed to correspond to or to overlap the concave portion 131a of the light extraction portion 131. Accordingly, the plurality of protrusion patterns 413a may overlap the plurality of concave portions 131a disposed in the light extraction portion 131, individually or in a one-to-one manner Therefore, each of the plurality of protrusion patterns 413a may greatly expand the size of the spectrum by re-dispersing the dispersion spectrum of the reflected light reflected from the plurality of concave portions 131a of the light extraction portion 131 in a radial form, so that it is possible to suppress or minimize the generation of the rainbow pattern in a radial form through mixing between adjacent spectra.

Each of the plurality of recessed patterns 413b may have a shape corresponding to or the same as the convex portion 131b of the light extraction portion 131. Each of the plurality of recessed patterns 413b may be disposed to correspond to (e.g., align with) or to overlap the convex portion 131b of the light extraction portion 131. Each of the plurality of recessed patterns 413b may overlap the convex portion 131b of the light extraction portion 131 without overlapping each of the plurality of concave portions 131a. For example, each of the plurality of recessed patterns 413b may include a bottom portion (or bottom surface), an upper portion (or upper surface) on the bottom portion, and an inclined portion (or curved portion) between the bottom portion and the upper portion. Each of the bottom, upper and inclined portions in each of the plurality of recessed patterns 413b may have the same shape (or structure) as each of the bottom portion (or bottom surface), upper portion and inclined portion of the convex portion 131b disposed in the light extraction portion 131.

Each of the plurality of recessed patterns 413b may be disposed to surround each of the plurality of protrusion patterns 413a. According to an embodiment of the present disclosure, each of the plurality of recessed patterns 413b may have a 6-angular shape in two-dimensionally. For example, each of the plurality of recessed patterns 413b may have a honeycomb structure or a hexagonal structure in two-dimensionally.

According to another embodiment of the present disclosure, the plurality of recessed patterns 413b may include a valley portion between the plurality of protrusion patterns 413a. For example, each of the plurality of recessed patterns 413b may be disposed between the plurality of protrusion patterns 413a and configured to be connected to each other to form a single recessed pattern (or valley pattern). Accordingly, one recessed pattern 413b is disposed to surround each of the plurality of protrusion patterns 413a, thereby to have a 6-angular shape in two-dimensionally. For example, one recessed pattern 413b may have a honeycomb or a hexagonal structure in two-dimensionally. Therefore, each of the plurality of recessed patterns 413b may greatly expand the size of the spectrum by re-dispersing the dispersion spectrum of the reflected light reflected from the convex portion 131b of the light extraction portion 131 in a radial form, so that it is possible to suppress or reduce the generation of the rainbow pattern in a radial form through mixing between adjacent spectra.

As described above, the light emitting display device according to another embodiment of the present disclosure includes the light guide portion 400 having the plurality of protrusion patterns 413a and the plurality of recessed patterns 413b which respectively correspond to or overlap the plurality of concave portions 131a and convex portions 131b disposed in the light extraction portion 131 of the planarization layer 130 so that it is possible to suppress or minimize the generation of the rainbow pattern in the radial form through mixing between adjacent spectra by re-dispersing the dispersion spectrum of the reflected light reflected from the light extraction portion 131 of the planarization layer 130 through the use of the plurality of protrusion patterns 413a and the plurality of recessed patterns 413b in a radial form so as to greatly expand the size of the spectrum, to thereby reduce the degradation of the black visibility characteristics caused by the reflected light by the light extraction portion 131.

FIG. 19 illustrates a light emitting display device according to another embodiment of the present disclosure. FIG. 19 is obtained by changing the light emitting display device shown in FIGS. 2 and 3 to a top emission structure. Accordingly, descriptions of the other elements except for the configuration related to the top emission structure of the light emitting display device may be omitted or will be briefly given.

Referring to FIG. 19, the light emitting display device according to another embodiment of the present disclosure may include a substrate 100, an encapsulation portion 200, an opposite substrate 300, and a light guide portion 400.

The substrate 100 may include a pixel circuit layer 110, a planarization layer 130 including a light extraction portion 131, and a light emitting device layer 150. The light extraction portion 131 may be disposed between the substrate 100 and the light guide portion 400. The substrate 100 may be substantially the same as the substrate 100 described in FIGS. 2 and 3 except that a first electrode E1 of the light emitting device layer 150 is formed of a reflective electrode material and a second electrode E2 is formed of a transparent electrode material, and thus, the repetitive description thereof may be omitted.

The encapsulation portion 200 may be disposed over the substrate 100 to protect the light emitting device layer 150. The encapsulation portion 200 may be substantially the same as the encapsulation portion 200 described in FIGS. 2 and 3, and thus, the repetitive description thereof may be omitted.

The opposite substrate 300 may be disposed over the substrate 100 to protect the encapsulation portion 200. The opposite substrate 300 may be substantially the same as the opposite substrate 300 described in FIGS. 2 and 3, and thus, the repetitive description thereof may be omitted. The opposite substrate 300 may be made of a transparent plastic material, but is not limited thereto.

The light emitting display device according to another embodiment of the present disclosure may further include a color filter layer 180 disposed between the encapsulation portion 200 and the opposite substrate 300.

The color filter layer 180 may be disposed between the encapsulation portion 200 and the opposite substrate 300 such that the color filter layer 180 overlaps at least one light emitting area EA. The color filter layer 180 may include a color filter that transmits only a wavelength of a color set in the pixel P (or subpixel) among the light emitted (or extracted) from the light emitting device layer 150 toward the opposite substrate 300.

The color filter layer 180 according to an embodiment of the present disclosure may be directly formed at an upper surface of the encapsulation portion 200 so as to overlap the light emitting area EA. For example, the color filter layer 180 may directly contact an upper surface of the encapsulation portion 200. The color filter layer 180 according to another embodiment of the present disclosure may be disposed at an inner surface of the opposite substrate 300 confronting the upper surface of the encapsulation portion 200 so as to overlap the light emitting area EA. For example, the opposite substrate 300 having the color filter layer 180 may be coupled to the encapsulation portion 200 by using a transparent adhesive member.

The light emitting display device according to another embodiment of the present disclosure may further include a black matrix 190 disposed between adjacent color filters of the color filter layer 180.

The black matrix 190 may overlap the remaining areas except for the light emitting area EA in each pixel P. Alternatively, the remaining area except for the light emitting area EA of each pixel P may include a stacked structure of at least two color filters instead of the black matrix 190. For example, the remaining areas except for the light emitting area EA of each pixel P may include a stacked structure of at least two of a red color filter, a green color filter, and a blue color filter. The stacked structure of at least two color filters may prevent a color mixture between the adjacent pixels P on behalf of the black matrix 190.

The light guide portion 400 may be coupled to a light emitting surface 300a by using an adhesive member (or a first transparent adhesive member) 450. The light guide portion 400 may be coupled to the light emitting surface 300a, which is an upper surface of the opposite substrate 300, by using the adhesive member 450. The light guide portion 400 may be substantially the same as any one of the light guide portions 400 described in FIGS. 3 to 18 except that the light guide portion 400 is coupled to the light emitting surface 300a, which is the upper surface of the opposite substrate 300, and thus, like reference numerals refer to like elements and their repetitive descriptions may be omitted. Alternatively, in the light emitting display device having the top emission structure, each of a plurality of protrusion patterns 413a disposed in the light guide portion 400 may correspond to or overlap a concave portion 131a of the light extraction portion 131, and the recessed pattern 413b disposed in the light guide portion 400 may be disposed to correspond to or to overlap the convex portion 131b of the light extraction portion 131, however, it is not limited thereto.

Accordingly, the light guide portion 400 may suppress or minimize the generation of rainbow pattern in the radial form through mixing between adjacent spectra by re-dispersing the dispersion spectrum of the reflected light reflected by the light extraction portion 131 of the planarization layer 130 and proceeding to the opposite substrate 300 in the radial form so as to greatly expand the size of the spectrum, thereby reducing or minimizing the degradation of the black visibility characteristics caused by the reflected light by the light extraction portion 131.

The light emitting display device according to another embodiment of the present disclosure may further include a polarization member 500 disposed over the light guide portion 400.

The polarization member 500 may be configured to block external light reflected by the light extraction portion 131 and the pixel circuit, or the like. For example, the polarization member 500 may be configured as a circularly polarization member or a circularly polarization film.

The polarization member 500 may be disposed at or coupled to an upper surface of the light guide portion 400 by using a coupling member (or a second transparent adhesive member) 550. Therefore, the light guide portion 400 may be disposed between the light emitting surface 300a and the polarization member 500.

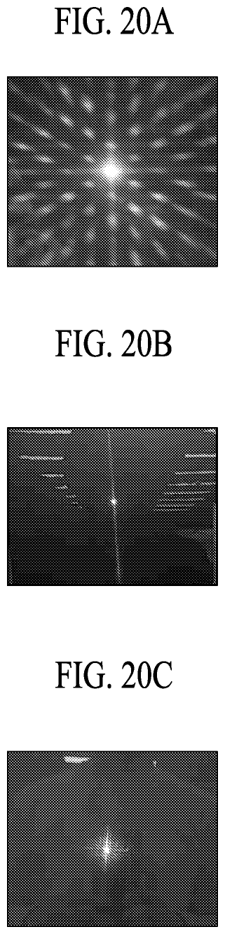

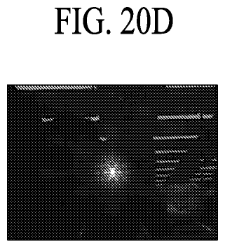

FIG. 20A is a photograph showing a black visibility characteristic of a light emitting display device according to an experimental example, and FIGS. 20B to 20D are photographs showing black visibility of the light emitting display device according to some embodiments of the present disclosure. In the experimental example, white light was irradiated at a distance of approximately 30 cm from the light emitting display device to photograph black visibility characteristics. In each of FIGS. 20A to 20D, the brightest white area is generated by the wavelength having the strongest intensity among the reflected light, and the surrounding white area is reflected by the indoor illumination of the experiment place.

The light emitting display device according to the experimental example shown in FIG. 20A includes only a light extraction portion disposed in a planarization layer without a light guide portion according to the embodiment of the present disclosure. The light emitting display device shown in FIG. 20B includes the light extraction portion disposed in the planarization layer and the light guide portion shown in FIG. 9. The light emitting display device shown in FIG. 20C includes the light extraction portion disposed in the planarization layer and the light guide portion shown in FIG. 13, and the light emitting display device shown in FIG. 20D includes the light extraction portion disposed in the planarization layer and the light guide portion shown in FIG. 17.

As known from FIG. 20A, the light emitting display device according to the experimental example generates the rainbow pattern of the radial shape by the reflected light reflected by the light extraction portion disposed in the planarization layer, thereby lowering the black visibility.

As known from FIGS. 20B to 20D, the light emitting display device according to the embodiments of the present disclosure may suppress or minimize the generation of rainbow patterns in the radial form by the reflected light reflected by the light extraction portion disposed in the planarization layer according to the light guide of the light guide portion, thereby reducing the degradation of the black visibility characteristics.

It will be apparent to those skilled in the art that the present disclosure described above is not limited by the above-described embodiments and the accompanying drawings and that various substitutions, modifications, and variations can be made in the present disclosure without departing from the spirit or scope of the disclosures. Consequently, the scope of the present disclosure is defined by the accompanying claims, and it is intended that all variations or modifications derived from the meaning, scope, and equivalent concept of the claims fall within the scope of the present disclosure.

What is claimed is:

1. A light emitting display device comprising:
a substrate including a plurality of pixels having a light emitting area;
a light extraction portion including a curved portion in the light emitting area;
a light emitting device layer over the light extraction portion, the light emitting device layer configured to emit light to a light emitting surface in the light emitting area; and
a light guide portion on the light emitting surface, the light guide portion including a light refraction pattern portion.

2. The light emitting display device according to claim 1, wherein the light refraction pattern portion includes a plurality of protrusion patterns and a plurality of recessed patterns, each of the plurality of recessed patterns between a pair of protrusion patterns from the plurality of protrusion patterns.

3. The light emitting display device according to claim 2, wherein each of the plurality of protrusion patterns has a triangular cross-sectional structure, and is disposed in parallel along at least one or more among a first direction of the substrate and a second direction that crosses the first direction.

4. The light emitting display device according to claim 2, wherein the light guide portion includes:
a first light guide member having the light refraction pattern portion; and
a second light guide member having another light refraction pattern portion,
wherein each of the plurality of protrusion patterns of the light refraction pattern portion of the first light guide member intersects with each of a plurality of protrusion patterns included in the another light refraction pattern portion of the second light guide member.

5. The light emitting display device according to claim 2, wherein the light extraction portion includes:
a plurality of concave portions; and
a convex portion disposed around each of the plurality of concave portions.

6. A light emitting display device comprising:
a substrate including a plurality of pixels having a light emitting area;
a planarization layer over the substrate, the planarization layer including a light extraction portion at a portion of the planarization layer in the light emitting area, the light extraction portion comprising a plurality of concave portions and a convex portion between the plurality of concave portions;
a light emitting device layer over the light extraction portion, the light emitting device layer configured to emit light to a light emitting surface in the light emitting area; and
a light guide portion on the light emitting surface, the light guide portion including a light refraction pattern portion,
wherein the light refraction pattern portion includes a light refractive pattern that overlaps at least one or more among the plurality of concave portions and the convex portion.

7. The light emitting display device according to claim 6, wherein the light refractive pattern portion includes a plurality of protrusion patterns and a plurality of recessed patterns, each of the plurality of recessed patterns between a pair of protrusion patterns from the plurality of protrusion patterns.

8. The light emitting display device according to claim 7, wherein the convex portion includes:
a vertex portion between adjacent two concave portions from the plurality of concave portions; and
a ridge portion between the adjacent two concave portions and connected between adjacent two vertex portions,
wherein the ridge portion is parallel with a first direction of the substrate, and
wherein each of the plurality of recessed portions is in parallel with the first direction.

9. The light emitting display device according to claim 7, wherein a distance between the plurality of protrusion patterns is less than or equal to a distance between the plurality of concave portions.

10. The light emitting display device according to claim 7, wherein each of the plurality of recessed patterns overlaps the convex portion without overlapping the plurality of concave portions.

11. The light emitting display device according to claim 10, wherein each of the plurality of recessed patterns is in parallel with at least one or more among a second direction that intersects a first direction of the substrate, a first diagonal direction between the first direction and the second direction, and a second diagonal direction that is symmetrical to the first diagonal direction with respect to the second direction.

12. The light emitting display device according to claim 7,
wherein the plurality of protrusion patterns overlaps each of the plurality of concave portions, and
wherein the plurality of recessed patterns overlaps each of the plurality of concave portions and the convex portion.

13. The light emitting display device according to claim 7,
wherein the convex portion comprises a honeycomb shape in a plan view of the light emitting display device, and
wherein each of the plurality of recessed pattern comprises the honeycomb shape which is substantially the same as the honeycomb shape of the convex portion.

14. The light emitting display device according to claim 7,
wherein the plurality of protrusion patterns overlaps each of the plurality of concave portions, and each of the plurality of recessed patterns overlaps the convex portion without overlapping the plurality of concave portions.

15. The light emitting display device according to claim 7, further comprising:
a coupling member; and
a polarization member coupled to the light guide portion via the coupling member,
wherein a refractive index of the coupling member is less than a refractive index of the light refraction pattern portion.

16. The light emitting display device according to claim 7, wherein the light guide portion further comprises:
an overlay layer overlaid with the light refraction pattern portion,
wherein a refractive index of the overlay layer is less than a refractive index of the light refraction pattern portion.

17. The light emitting display device according to claim 7, further comprising:
a polarization member coupled to the light guide portion.

18. The light emitting display device according to claim 7, wherein the substrate is between the light guide portion and the light extraction portion, or the light extraction portion is between the substrate and the light guide portion.

19. The light emitting display device according to claim 7, further comprising:
a color filter layer between the light extraction portion and the substrate,
wherein the substrate is between the light guide portion and the light extraction portion.

20. The light emitting display device according to claim 7, wherein an arrangement region of the light extraction portion is wider than the light emitting area.

21. A display apparatus comprising:
a substrate including a light emitting area;
a subpixel on the substrate, the subpixel including a light emitting element configured to emit light in the light emitting area;
a planarization layer between the substrate and the light emitting element, the planarization layer including a plurality of concave portions in the light emitting area and a plurality of convex portions in the light emitting area; and
a light guide on the substrate, the light guide including a plurality of protrusions and a plurality of recesses in the light emitting area,
wherein the plurality of protrusions and the plurality of recesses of the light guide portion overlap the plurality of concave portions and the plurality of convex portions of the planarization layer in the light emission area.

22. The display apparatus according to claim 21, wherein a recess from the plurality of recesses overlaps a corresponding convex portion from the plurality of convex portions, and a protrusion from the plurality of protrusions overlaps a corresponding concave portion from the plurality of concave portions.

23. The display apparatus according to claim 21, wherein each of the plurality of protrusions has a triangular cross-sectional structure, and is disposed in parallel along at least one or more among a first direction of the substrate and a second direction that crosses the first direction.

24. The display apparatus according to claim 21, wherein each of the plurality of protrusions and each of the plurality of recesses has a curved surface.

25. The display apparatus according to claim 21, wherein the light guide is closer to the substrate than the planarization layer or the planarization layer is closer to the substrate than the light guide.
